(19) United States
(12) Patent Application Publication
(10) Pub. No.: US 2024/0429253 A1
(43) Pub. Date: Dec. 26, 2024

(54) SEMICONDUCTOR APPARATUS AND ELECTRONIC DEVICE

(71) Applicant: SONY SEMICONDUCTOR SOLUTIONS CORPORATION, KANAGAWA (JP)

(72) Inventors: TASUKU OGAMI, KANAGAWA (JP); TSUYOSHI WATANABE, KANAGAWA (JP)

(21) Appl. No.: 18/703,076

(22) PCT Filed: Sep. 5, 2022
(86) PCT No.: PCT/JP2022/033249

§ 371 Date: Apr. 19, 2024

(30) Foreign Application Priority Data
Oct. 27, 2021 (JP) 2021-175146

(51) Int. Cl. H01L 27/146

(52) U.S. Cl. CPC H01L 27/14618; H01L 27/14601; H01L 27/14636

(57) ABSTRACT

Provided is a semiconductor apparatus capable of improving the capability to suppress condensation on a cover plate. A thermoelectric element module is disposed between a sensor chip and a cover plate. Further, the thermoelectric element module includes a first electrode formed in a region (third region) within an upper surface of the sensor chip, the third region being on an edge side of the sensor chip with respect to a pixel region, a second electrode formed in a region within a lower surface of the cover plate, the region facing the third region, and thermoelectric elements disposed between the first electrode and the second electrode and configured to be electrically connected to the first electrode and the second electrode so as to absorb heat from the sensor chip and dissipate the heat to the cover plate.

### TECHNICAL FIELD

The present technology (the technology according to the present disclosure) relates to a semiconductor apparatus and an electronic device.

### BACKGROUND ART

In the past, for example, a semiconductor apparatus in which a Peltier element and a semiconductor element are disposed in this order on a bottom surface of a recess portion of a package substrate and, moreover, a cover plate covers an opening portion of the recess portion has been proposed (refer to PTL 1, for example). In the semiconductor apparatus described in PTL 1, heat of the semiconductor element is absorbed by the Peltier element and dissipated to the package substrate, and a temperature of the cover plate is raised by the heat of the package substrate such that condensation on the cover plate is suppressed.

### CITATION LIST

### Patent Literature

### [PTL 1]

JP 2015-135932A

### SUMMARY

### Technical Problem

Such a semiconductor apparatus is required to further improve capability to suppress condensation.

It is an object of the present disclosure to provide a semiconductor apparatus and an electronic device capable of improving the capability to suppress condensation on a cover plate.

### Solution to Problem

A semiconductor apparatus according to the present disclosure includes (a) a package substrate having a recess portion on a first surface, (b) a sensor chip disposed inside the recess portion and having a pixel region in which photoelectric conversion sections are arranged, (c) a transparent cover plate disposed on the first surface and covering an opening portion of the recess portion, and (d) a thermoelectric element module disposed between the sensor chip and the cover plate, (e) in which the thermoelectric element module includes a first electrode formed in a region within a surface of the sensor chip facing the cover plate, the region being on an edge side of the sensor chip with respect to the pixel region, a second electrode formed in a region within a surface of the cover plate facing the sensor chip, the region facing the region on the edge side, and at least a pair of thermoelectric elements disposed between the first and second electrodes and configured to be electrically connected to the first and second electrodes so as to absorb heat from the sensor chip and dissipate the heat to the cover plate.

Further, another semiconductor apparatus according to the present disclosure includes (a) a package substrate having a recess portion on a first surface, (b) a sensor chip disposed inside the recess portion and having a pixel region in which photoelectric conversion sections are arranged, (c) a transparent cover plate disposed on the first surface and covering an opening portion of the recess portion, and (d) a resistive heating element disposed in a region within a surface of the cover plate facing the sensor chip, the region excluding a region facing the pixel region.

Further, an electronic device according to the present disclosure includes a semiconductor apparatus including (a) a package substrate having a recess portion on a first surface, (b) a sensor chip disposed inside the recess portion and having a pixel region in which photoelectric conversion sections are arranged, (c) a transparent cover plate disposed on the first surface and covering an opening portion of the recess portion, and (d) a thermoelectric element module disposed between the sensor chip and the cover plate, (e) in which the thermoelectric element module includes a first electrode formed in a region within a surface of the sensor chip facing the cover plate, the region being on an edge side of the sensor chip with respect to the pixel region, a second electrode formed in a region within a surface of the cover plate facing the sensor chip, the region facing the region on the edge side, and at least a pair of thermoelectric elements disposed between the first and second electrodes and configured to be electrically connected to the first and second electrodes so as to absorb heat from the sensor chip and dissipate the heat to the cover plate.

Further, another electronic device according to the present disclosure includes a semiconductor apparatus including (a) a package substrate having a recess portion on a first surface, (b) a sensor chip disposed inside the recess portion and having a pixel region in which photoelectric conversion sections are arranged, (c) a cover plate disposed on the first surface and covering an opening portion of the recess portion, and (d) a resistive heating element disposed in a region within a surface of the cover plate facing the sensor chip, the region excluding a region facing the pixel region.

### BRIEF DESCRIPTION OF DRAWINGS

FIG. 1 is a view depicting an overall schematic configuration of a semiconductor apparatus according to a first embodiment.

FIG. 2 is a view depicting a planar configuration of a sensor chip in a case where the sensor chip is viewed from a line A-A side of FIG. 1.

FIG. 3 is a view depicting a planar configuration of a package substrate in a case where the package substrate is viewed from a line B-B side of FIG. 1.

FIG. 4 is a view depicting planar configurations of a cover plate, a metal film, and so forth in a case where the cover plate, the metal film, and so forth are viewed from a line C-C side of FIG. 1.

FIG. 5 is a view depicting a cross-sectional configuration of a thermoelectric element module in a case where the thermoelectric element module is taken along line D-D of FIG. 1.

FIG. 6 is a view depicting a cross-sectional configuration of the thermoelectric element module in a case where the thermoelectric element module is taken along line E-E of FIG. 1.

FIG. 7 is a view depicting a method of manufacturing the semiconductor apparatus according to the first embodiment and depicting a glass manufacturing flow.

FIG. 8 is a view depicting the method of manufacturing the semiconductor apparatus according to the first embodiment and depicting a chip manufacturing flow.

FIG. 9 is a view depicting the method of manufacturing the semiconductor apparatus according to the first embodiment and depicting a package assembly flow.

FIG. 10 is a view depicting the method of manufacturing the semiconductor apparatus according to the first embodiment and depicting the package assembly flow.

FIG. 11 is a view depicting an overall schematic configuration of the semiconductor apparatus according to a modification.

FIG. 12 is a diagram depicting a psychrometric chart at an

FIG. 13 is a diagram depicting a simulation result before and after an operation of the thermoelectric element module.

FIG. 14 is a view depicting an overall schematic configuration of the semiconductor apparatus according to a modification.

FIG. 15 is a view depicting a method of manufacturing the semiconductor apparatus according to the modification.

FIG. 16 is a view depicting the method of manufacturing the semiconductor apparatus according to the modification.

FIG. 17 is a view depicting an overall schematic configuration of the semiconductor apparatus according to a modification.

FIG. 18 is a view depicting a cross-sectional configuration of the thermoelectric element module in a case where the thermoelectric element module is taken along line F-F of FIG. 17.

FIG. 19 is a view depicting a cross-sectional configuration of the thermoelectric element module in a case where the thermoelectric element module is taken along line G-G of FIG. 17.

FIG. 20 is a view depicting an overall schematic configuration of the semiconductor apparatus according to a second embodiment.

FIG. 21 is a view depicting a planar configuration of the sensor chip in a case where the sensor chip is viewed from a line H-H side of FIG. 20.

FIG. 22 is a view depicting a planar configuration of the package substrate in a case where the package substrate is viewed from a line I-I side of FIG. 20.

FIG. 23 is a view depicting planar configurations of the cover plate, resistive heating elements, and so forth in a case where the cover plate, the resistive heating elements, and so forth are viewed from a line J-J side of FIG. 20.

FIG. 24 is a view depicting planar configurations of the cover plate, the resistive heating elements, and so forth in a case where the cover plate, the resistive heating elements, and so forth are viewed from a line J-J side of FIG. 20 and including a heat insulating member and silver pastes.

FIG. 25 is a view depicting a method of manufacturing the semiconductor apparatus according to the second embodiment and depicting a glass manufacturing flow.

FIG. 26 is a view depicting the method of manufacturing the semiconductor apparatus according to the second embodiment and depicting a package assembly flow.

FIG. 27 is a view depicting the method of manufacturing the semiconductor apparatus according to the second embodiment and depicting the package assembly flow.

FIG. 28 is a view depicting the method of manufacturing the semiconductor apparatus according to the second embodiment and depicting the package assembly flow.

FIG. 29 is a view depicting the method of manufacturing the semiconductor apparatus according to a modification.

FIG. 30 is a diagram depicting an example of a schematic configuration of an imaging apparatus as an electronic device to which the present technology is applied.

### DESCRIPTION OF EMBODIMENTS

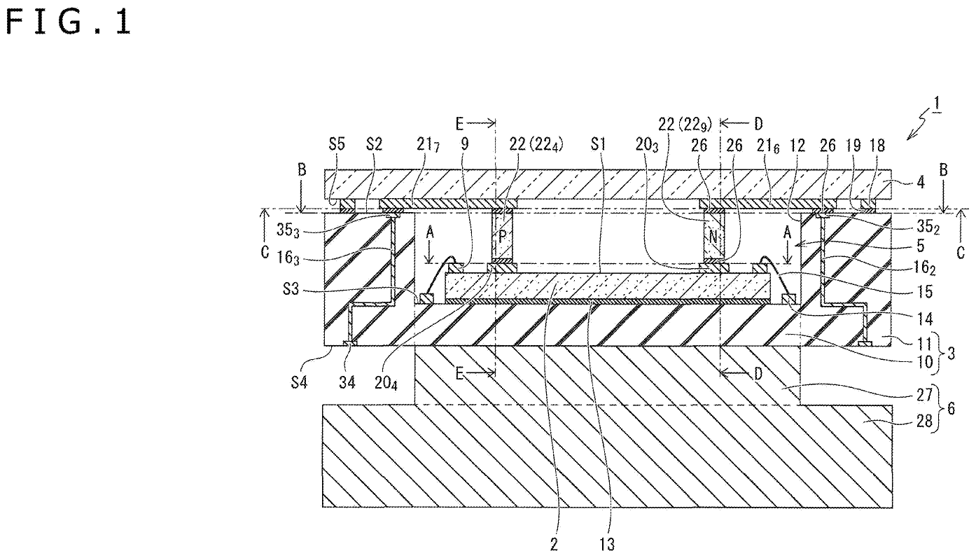

An example of a semiconductor apparatus and an electronic device according to embodiments of the present disclosure will be described below with reference to FIGS. 1 to 30. The embodiments of the present disclosure will be described in the following order. It is noted that the present disclosure is not limited to the following examples. Further, the effects described in the present specification are illustrative only and are not limited. Further, there may also be additional effects.
1. First Embodiment: Semiconductor Apparatus
   1-1 Overall Configuration of Semiconductor Apparatus
   1-2 Method of Manufacturing Semiconductor Apparatus
   1-3 Modifications
2. Second Embodiment: Semiconductor Apparatus
   2-1 Overall Configuration of Semiconductor Apparatus
   2-2 Method of Manufacturing Semiconductor Apparatus
   2-3 Modifications
3. Electronic Device

### 1. First Embodiment: Semiconductor Apparatus

### 1-1 Overall Configuration of Semiconductor Apparatus

A semiconductor apparatus 1 according to a first embodiment of the present disclosure will be described. FIG. 1 is a view depicting an overall schematic configuration of the semiconductor apparatus 1 according to the first embodiment. As depicted in FIG. 1, the semiconductor apparatus 1 includes a sensor chip 2, a package substrate 3, a cover plate 4, a thermoelectric element module 5, and a heat dissipation mechanism 6.

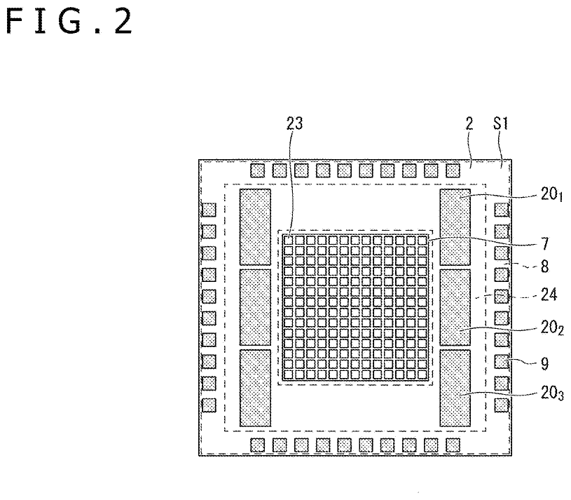

The sensor chip 2 is, for example, a sensor chip of a SWIR (Short Wavelength Infra-Red; Short wavelength infrared) image sensor or a CMOS (Complementary Metal-Oxide-Semiconductor) image sensor. As depicted in FIG. 2, a pixel region 7 is formed in a central portion of a light-incident surface (hereinafter also referred to as an “upper surface S1”) of the sensor chip 2. FIG. 2 is a view depicting a planar configuration of the sensor chip 2 in a case where the sensor chip 2 is viewed from an A-A line side of FIG. 1. In the pixel region 7, pixels, on-chip lenses, color filters, and so forth are arranged. The pixels include photoelectric conversion sections 23, which perform photoelectric conversion according to the amount of irradiated light. The on-chip lenses are disposed for respective pixels and focus irradiated light onto the respective pixels. The color filters are disposed for respective pixels and allow light of desired wavelengths to enter the respective pixels. That is, a plurality of photoelectric conversion sections 23 are arranged in the pixel region 7. For example, a photodiode including a p-type semiconductor region and an n-type semiconductor region can be employed as each photoelectric conversion section 23. Accordingly, in the pixel region 7, irradiated light passes through the microlens and the color filters, and the light that has passed therethrough is photoelectrically converted by the photoelectric conversion sections 23 and output as pixel signals. FIG. 2 exemplifies a case where the sensor chip 2 is a rectangular chip in a planar view.

Further, in an outermost region (hereinafter also referred to as a “first region 8”) within a region on an edge side with respect to the pixel region 7 of the upper surface S1 of the sensor chip 2, a plurality of bonding pads 9, which are linearly arranged along the edge of the sensor chip 2, are formed. The bonding pads 9 are regions where conductors connected to wirings inside the sensor chip 2 to exchange electrical signals with an external substrate and so forth are disposed. For example, copper pads can be employed as the conductors.

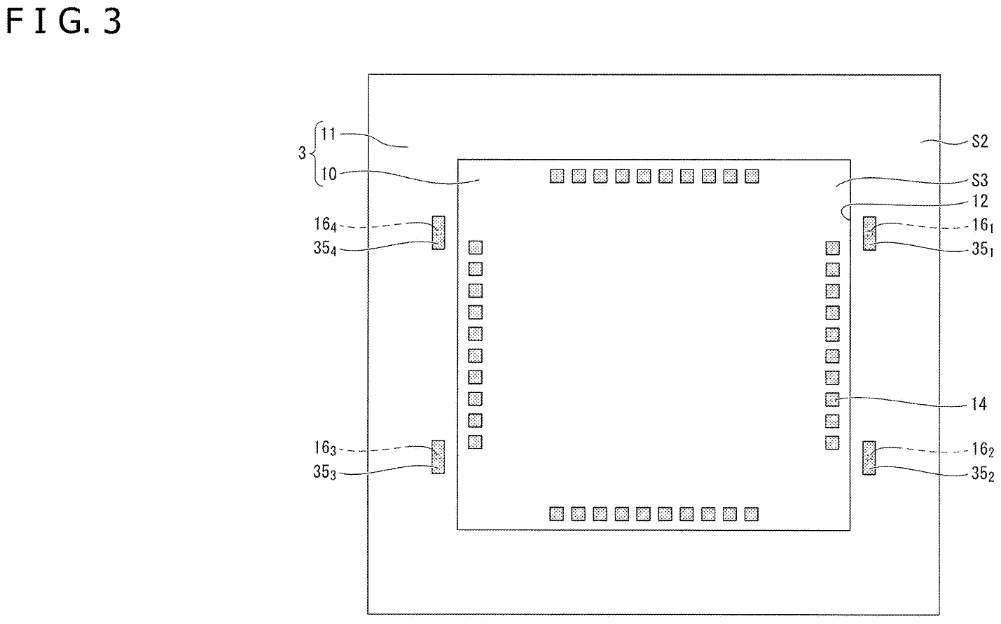

The package substrate 3 is a substrate for housing the sensor chip 2. As depicted in FIGS. 1 and 3, the package substrate 3 has a bottom portion 10 and an annular wall portion 11, which is disposed around the bottom portion 10. Accordingly, a recess portion 12 is formed on a light-incident surface (a “first surface” in a broad sense; Hereinafter also referred to as an “upper surface S2”) of the package substrate 3. FIG. 3 is a view depicting a planar configuration of the package substrate 3 in a case where the package substrate 3 is viewed from a B-B line side of FIG. 1. FIG. 3 exemplifies a case where an external shape of the package substrate 3 and a shape of an opening portion of the recess portion 12 are rectangular in a planar view. For example, a multilayer substrate including ceramics such as aluminum oxide (Al₂O₃) can be employed as the package substrate 3. One example is a PGA (pin Grid Array) substrate. A plurality of wirings are formed in multiple layers in the interior of the package substrate located between an upper surface S3 of the bottom portion 10 and a surface (hereinafter also referred to as a “lower surface S4”) on an opposite side of the upper surface S3. Each wiring is connected to a plurality of terminals (not depicted) formed on an edge side and so forth of the lower surface S4 of the package substrate 3.

Further, the sensor chip 2 is disposed in a central portion of the upper surface S3 of the bottom portion 10 of the package substrate 3. Accordingly, the sensor chip 2 is housed in an interior space of the recess portion 12 of the package substrate 3. The upper surface S3 of the bottom portion 10 and the sensor chip 2 are bonded to each other by an adhesive 13.

Further, bonding pads 14 are formed in a region that is within the upper surface S3 of the bottom portion 10 of the package substrate 3 and that is on an edge side with respect to a region of the upper surface S3 on which the sensor chip 2 is disposed. The bonding pads 14 are regions where conductors connected to wirings inside the package substrate 3 to exchange electrical signals with the sensor chip 2 are disposed. The bonding pads 14 are electrically connected to the bonding pads 9 on the sensor chip 2 via bonding wires 15. Accordingly, the bonding pads 9 on the sensor chip 2 are electrically connected to the plurality of terminals formed on the edge side and so forth of the lower surface S4 of the package substrate 3, and the package substrate 3 can externally output pixel signals output from the sensor chip 2.

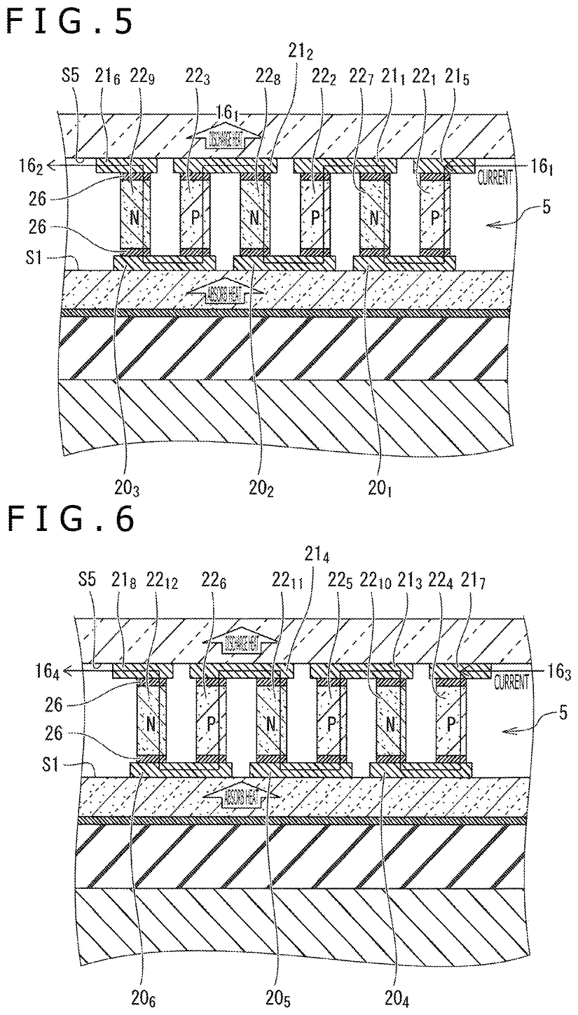

Further, a plurality of interior wirings 16₁, 16₂, 16₃, and 16₄ are disposed inside the wall portion 11, as depicted in FIGS. 1 and 3. Each of the interior wirings 161 to 164 is a wiring having one end connected to a terminal (hereinafter also referred to as a “first terminal 34”) exposed from the lower surface S4 of the package substrate 3 and the other end connected to a terminal (hereinafter also referred to as a “second terminal 35₁, 35₂, 35₃, or 35₄”) exposed from the upper surface S2. FIG. 3 exemplifies a case where, in a planar view, the interior wiring 16₁ is disposed on an upper right side of the recess portion 12, the interior wiring 16₂ is disposed on a lower right side of the recess portion 12, the interior wiring 16₃ is disposed on a lower left side of the recess portion 12, and the interior wiring 16₄ is disposed on an upper left side of the recess portion 12. Further, the interior wiring 16₁ is connected via the second terminal 35₁ to a thermoelectric element 22₁, which is located at an end portion of series-connected thermoelectric elements 22₁, 22₇, 22₂, 22₈, 22₃, and 22₉ depicted in FIG. 5, and the interior wiring 16₂ is connected via the second terminal 352 to the thermoelectric element 22₉, which is located at an opposite end portion. Further, the interior wiring 16₃ is connected via the second terminal 35₃ to a thermoelectric element 22₄, which is located at an end portion of series-connected thermoelectric elements 22₄, 22₁₀, 22₅, 22₁₁, 22₆, and 22₁₂ depicted in FIG. 6, and the interior wiring 16₄ is connected via the second terminal 35₄ to the thermoelectric element 22₁₂, which is located at an opposite end portion. Accordingly, the interior wirings 16₁ to 16₄ allow current to pass through (energize) the thermoelectric element module 5.

The cover plate 4 is a transparent plate for sealing the interior space of the recess portion 12. As depicted in FIG. 1, the cover plate 4 is disposed on the upper surface S2 of the package substrate 3 and covers the opening portion of the recess portion 12 such that the interior space is formed inside the recess portion 12. A material such as borosilicate glass that can pass light therethrough can be employed as a material for the cover plate 4. Accordingly, the cover plate 4 can pass light from a subject therethrough, allowing the light to be incident on the pixel region 7.

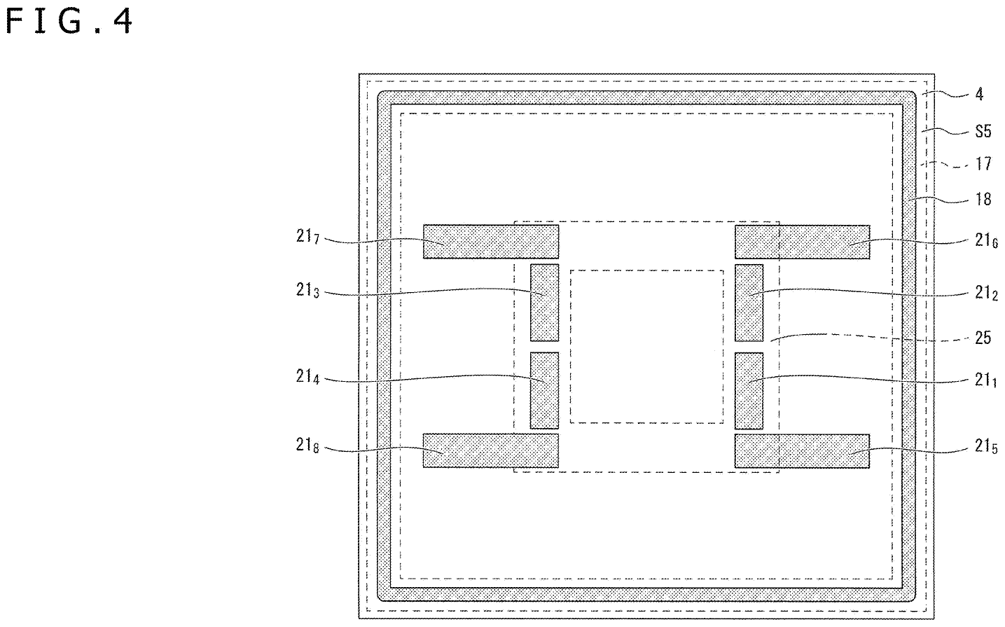

Further, as depicted in FIGS. 1 and 4, a metal film 18, which is formed in an annular shape along an edge portion of the cover plate 4, is formed in a region (hereinafter also referred to as a “second region 17”) that is within a surface (hereinafter also referred to as a “lower surface S5”) of the cover plate 4 facing the sensor chip 2 and that is on an edge side of a region facing the wall portion 11. FIG. 4 is a view depicting planar configurations of the cover plate 4, the metal film 18, and so forth in a case where the cover plate 4, the metal film 18, and so forth are viewed from a C-C line side of FIG. 1. For example, a metal that can form an alloy layer with a solder can be employed as a material for the metal film 18. One example is copper.

Further, as depicted in FIG. 1, a sealing member 19 is disposed so as to surround the opening portion of the recess portion 12 between the metal film 18 of the cover plate 4 and the upper surface S2 of the package substrate 3. For example, a solder can be employed as a material for the sealing member 19. Accordingly, the sealing member 19 seals a gap between the package substrate 3 and the cover plate 4 and hermetically seals the interior space of the recess portion 12 of the package substrate 3. Thus, for example, hermetically sealing the interior space using the sealing member 19 in a dehumidified atmosphere can further improve the capability to suppress condensation. In a case where a solder is employed as the material for the sealing member 19, sealing using the sealing member 19 can also be performed in a solder reflow process in which second electrodes 21₁ to 21₈ are joined with the thermoelectric elements 22₁ to 22₁₂.

The thermoelectric element module 5 is a module (constituent component) disposed between the sensor chip 2 and the cover plate 4 to absorb heat from the sensor chip 2 and dissipate the heat to the cover plate 4. As depicted in FIGS. 2, 4, 5, and 6, the thermoelectric element module 5 includes first electrodes 20₁, 20₂, 20₃, 20₄, 20₅, and 20₆, the second electrodes 21₁, 21₂, 21₃, 21₄, 21₅, 21₆, 21₇, and 21₈, and at least one pair of the thermoelectric elements 22₁, 22₂, 22₃, 22₄, 22₅, 22₆, 22₇, 22₈, 22₉, 22₁₀, 22₁₁, and 22₁₂. FIG. 5 is a view depicting a cross-sectional configuration of the thermoelectric element module 5 in a case where the thermoelectric element module 5 is taken along line D-D of FIG. 1. Further, FIG. 6 is a view depicting a cross-sectional configuration of the thermoelectric element module 5 in a case where the thermoelectric element module 5 is taken along line E-E of FIG. 1. Further, a pair of thermoelectric elements includes a P-type thermoelectric element and an N-type thermoelectric element. FIGS. 5 and 6 exemplify a case where three pairs of thermoelectric elements are disposed on each of the left and right sides of the pixel region 7.

As depicted in FIG. 2, the first electrodes 20₁ to 20₆ are formed in a region (hereinafter also referred to as a “third region 24”) that is located on the edge side with respect to the pixel region 7 within the upper surface S1 of the sensor chip 2 and that is between the pixel region 7 and the first region 8. Each of the first electrodes 20₁ to 20₆ is arranged along the edge of the pixel region 7. The adjacent first electrodes 20₁ to 20₆ are spaced from each other by a predetermined distance. FIG. 2 exemplifies a case where the first electrodes 20₁ to 20₃ are linearly arranged on a right side of the pixel region 7 and the first electrodes 20₄ to 20₆ are linearly arranged on a left side of the pixel region 7 in a planar view. For example, copper can be employed as a material for the first electrodes 20₁ to 20₆.

The second electrodes 21₁ to 21₆ are formed in a region (hereinafter also referred to as a “fourth region 25”) that is within the lower surface S5 of the cover plate 4 and that faces the third region 24 of the sensor chip 2, as depicted in FIGS. 4, 5, and 6. The second electrodes 21₁ to 21₄ among the second electrodes 21₁ to 21₆ are arranged so as to straddle the adjacent first electrodes 20₁ to 20₆ in a case where the second electrodes 21₁ to 21₆ are viewed in a planar view. The adjacent second electrodes 21₁ to 21₄ are spaced from each other by the same distance as the distance between the first electrodes 20₁ to 20₆. FIGS. 4, 5, and 6 exemplify a case where, in a planar view, the second electrode 21₁ is disposed so as to straddle the first electrodes 20₁ and 20₂, the second electrode 21₂ is disposed so as to straddle the first electrodes 20₂ and 20₃, the second electrode 21₃ is disposed so as to straddle the first electrodes 20₄ and 20₅, and the second electrode 21₄ is disposed so as to straddle the first electrodes 20₅ and 20₆.

By contrast, the second electrodes 21₅ to 21₈ are arranged so as to straddle the thermoelectric elements 22₁, 22₄, 22₉, and 22₁₂ and the second terminals 35₁ to 35₆ in a planar view, as depicted in FIGS. 3 and 4. That is, the second electrodes 21₅ to 21₈ are formed in a region through which light toward the pixel region 7 does not pass. FIGS. 3 and 4 exemplify a case where, in a planar view, the second electrode 21₅ is disposed so as to straddle the thermoelectric element 22₁, which is located at an end portion of the series-connected thermoelectric elements 22₁ . . . 22₉ depicted in FIG. 5, and the second terminal 35₁, and the second electrode 21₆ is disposed so as to straddle the thermoelectric element 22₉, which is located at an opposite end portion, and the second terminal 35₂ of the wall portion 11. Further, FIGS. 3 and 4 exemplify a case where the second electrode 21₇ is disposed so as to straddle the thermoelectric element 22₄, which is located at an end portion of the series-connected thermoelectric elements 22₄ . . . 22₁₂ depicted in FIG. 6, and the second terminal 35₃, and the second electrode 21₈ is disposed so as to straddle the thermoelectric element 22₁₂, which is located at an opposite end portion, and the second terminal 35₄. For example, copper can be employed as a material for the second electrodes 21₁ to 21₈.

The thermoelectric elements 22₁ to 22₁₂ are disposed between the first electrodes 20₁ to 20₆ and the second electrodes 21₁ to 21₈, as depicted in FIGS. 5 and 6. The thermoelectric elements 22₁ to 22₁₂ are each electrically connected to a corresponding one of the first electrodes 20₁ to 20₆ and a corresponding one of the second electrodes 21₁ to 21₈ so as to absorb heat from the sensor chip 2 and dissipate the heat to the cover plate 4. The thermoelectric elements 22₁ to 22₁₂ and the first electrodes 20₁ to 20₆, the thermoelectric elements 22₁ to 22₁₂ and the second electrodes 21₁ to 21₈, and the second electrodes 21₅ to 21₈ and the second terminals 35₁ to 35₄ are electrically connected to each other by solders 26. For example, P-type thermoelectric elements and N-type thermoelectric elements can be employed as the thermoelectric elements 22₁ to 22₁₂.

FIGS. 5 and 6 exemplify a case where the P-type thermoelectric elements 22₁ to 22₆ and the N-type thermoelectric elements 22₇ to 22₁₂ are used as the thermoelectric elements 22₁ to 22₁₂. Among them, in FIG. 5, the P-type thermoelectric elements 22₁ to 22₃ and the N-type thermoelectric elements 22₇ to 22₉ are alternately arranged (22₁→22₇→22₂→22₈→22₃→22₉) on the right side of the pixel region 7 depicted in FIG. 2. End portions of the adjacent P-type thermoelectric element 22₁ and N-type thermoelectric element 22₇, the adjacent P-type thermoelectric element 22₂ and N-type thermoelectric element 22₈, and the adjacent P-type thermoelectric element 22₃ and N-type thermoelectric element 22₉ on a sensor chip 2 side are electrically connected to each other by the first electrodes 20₁ to 20₃, respectively. Further, end portions of the adjacent N-type thermoelectric element 22₇ and P-type thermoelectric element 22₂ and the adjacent N-type thermoelectric element 22₈ and P-type thermoelectric element 22₃ on a cover plate 4 side are electrically connected to each other by the second electrodes 21₁ and 21₂, respectively. Accordingly, the P-type thermoelectric elements 22₁ to 22₃ and the N-type thermoelectric elements 22₇ to 22₉ are alternately connected to each other in series.

Further, in FIG. 6, the P-type thermoelectric elements 22₄ to 22₆ and the N-type thermoelectric elements 22₁₀ to 22₁₂ are alternately arranged (22₄→22₁₀→22₅→22₁₁→22₆→22₁₂) on the left side of the pixel region 7. End portions of the adjacent P-type thermoelectric element 22₄ and N-type thermoelectric element 22₁₀, the adjacent P-type thermoelectric element 22₅ and N-type thermoelectric element 22₁₁, and the adjacent P-type thermoelectric element 22₆ and N-type thermoelectric element 22₁₂ on the sensor chip 2 side are electrically connected to each other by the first electrodes 20₄ to 9₆, respectively. Further, end portions of the adjacent N-type thermoelectric element 22₁₀ and P-type thermoelectric element 22₅ and the adjacent N-type thermoelectric element 22₁₁ and P-type thermoelectric element 22₆ on the cover plate 4 side are electrically connected to each other by the second electrodes 21₃ and 21₄, respectively. Accordingly, the P-type thermoelectric elements 22₄ to 22₆ and the N-type thermoelectric elements 22₁₀ to 22₁₂ are alternately connected to each other in series.

With such a configuration, in the thermoelectric element module 5, for example, current flowing from a thermoelectric element 22₁ side to a thermoelectric element 22₉ side can pass through the series-connected thermoelectric elements 22₁ . . . 22₉ depicted in FIG. 5 when a voltage is applied to the interior wirings 16₁ and 16₂. Further, for example, current flowing from a thermoelectric element 22₄ side to a thermoelectric element 22₁₂ side can pass through the series-connected thermoelectric elements 22₄ . . . 22₁₂ depicted in FIG. 6 when a voltage is applied to the interior wirings 16₃ and 16₄. In addition, the current flowing therethrough can generate a Peltier effect in the thermoelectric elements 22₁ to 22₁₂, and heat can be absorbed from the sensor chip 2 and dissipated to the cover plate 4. This allows the temperature of the cover plate 4 to rise and the condensation on the cover plate 4 to be suppressed. At the same time, the sensor chip 2 can be cooled.

The heat dissipation mechanism 6 is a mechanism that dissipates heat from the package substrate 3. As depicted in FIG. 1, the heat dissipation mechanism 6 is disposed on the lower surface S4 of the package substrate 3. For example, a heat sink including a plurality of heat dissipation fins or a cold plate to and from which cooling liquid flows in and out can be employed as the heat dissipation mechanism 6. FIG. 1 exemplifies a case where a heat sink in which a base portion 27 contacts a central portion of the lower surface S4 of the package substrate 3 and a plurality of heat dissipation fins 28 extend to an opposite side of a package substrate 3 side is used as the heat dissipation mechanism 6. Accordingly, the heat dissipation mechanism 6 can dissipate the heat of the sensor chip 2 via the package substrate 3, thereby further improving the cooling performance of the sensor chip 2.

### 1-2 Method of Manufacturing Semiconductor Apparatus

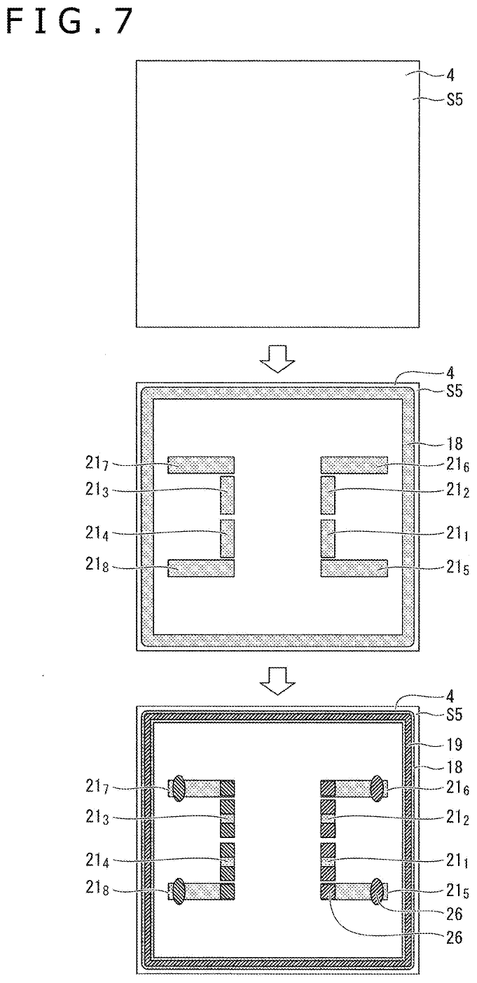

Next, a method of manufacturing the semiconductor apparatus 1 according to the first embodiment will be described. FIGS. 7, 8, 9, and 10 are views depicting the method of manufacturing the semiconductor apparatus 1 according to the first embodiment. Here, a solder used as the material for the sealing member 19 is also referred to as a “solder 19” and the upper surface S3 of the bottom portion 10 of the package substrate 3 is also referred to as a “bottom surface S3 of the recess portion 12.”

In the manufacturing method according to the first embodiment, a glass manufacturing flow, a chip manufacturing flow, and a package assembly flow are performed in this order. First, the glass manufacturing flow is performed. As depicted in FIG. 7, the cover plate 4 is prepared, and one surface (the lower surface S5) of the prepared cover plate 4 is subjected to copper plating to form the second electrodes 21₁ to 21₈ and the metal film 18. Subsequently, the solder 19 or 26 is applied on each of the formed second electrodes 21₁ to 21₈ and metal film 18.

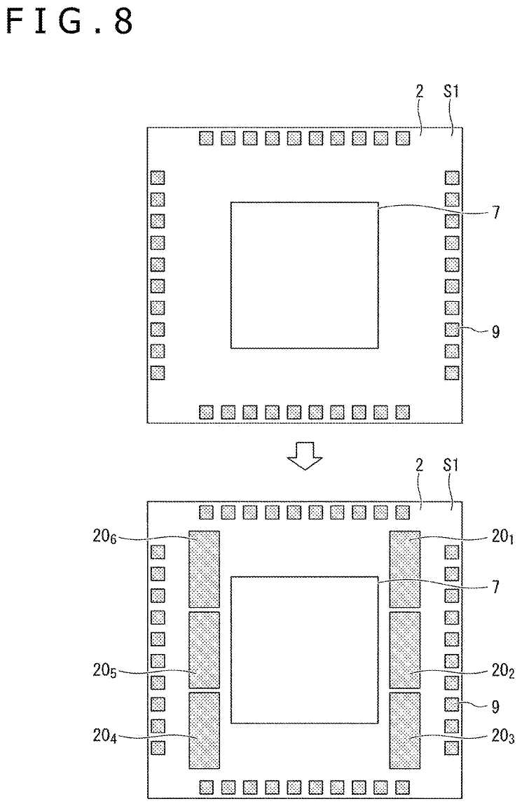

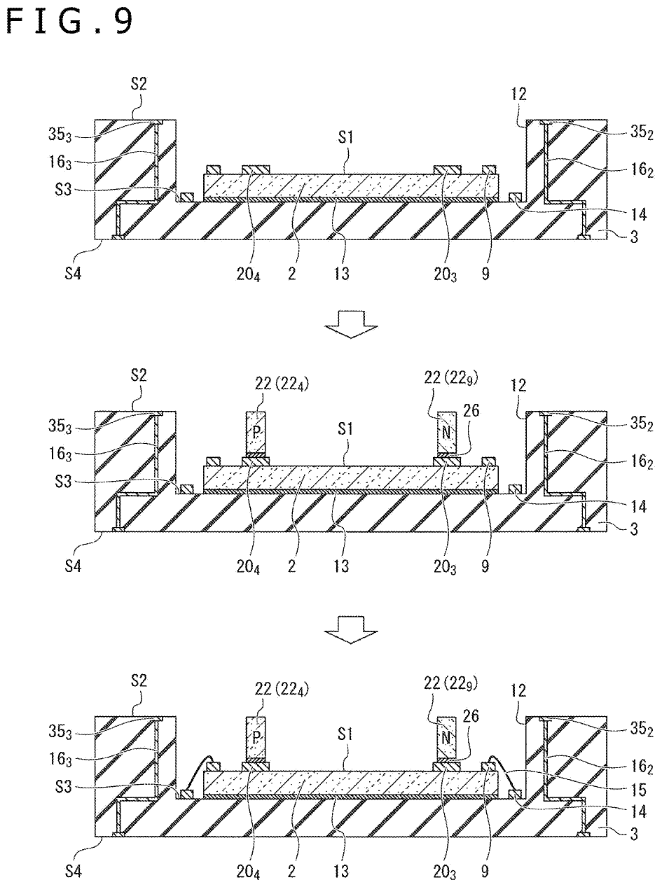

Subsequently, the chip manufacturing flow is performed. As depicted in FIG. 8, the sensor chip 2 is prepared, and the upper surface S1 of the sensor chip 2 is subjected to copper plating to form the first electrodes 20₁ to 20₆.

Subsequently, the package assembly flow is performed. In the package assembly flow, as depicted in FIG. 9, the sensor chip 2 on which the first electrodes 20₁ to 20₆ have been formed is bonded to the bottom surface S3 of the recess portion 12 of the package substrate 3 via the adhesive 13. At this time, thermal curing for heating and curing the adhesive 13 is performed. Subsequently, the thermoelectric elements 22₁ to 22₁₂ are joined (solder-joined) with the first electrodes 20₁ to 20₆ of the bonded sensor chip 2 via the solders 26. Subsequently, the bonding pads 9 on the sensor chip 2 and the bonding pads 14 on the package substrate 3 are electrically connected to each other via the bonding wires 15. Accordingly, the sensor chip 2 and a plurality of terminals (not depicted) formed on the edge side and so forth of the lower surface S4 of the package substrate 3 are electrically connected to each other.

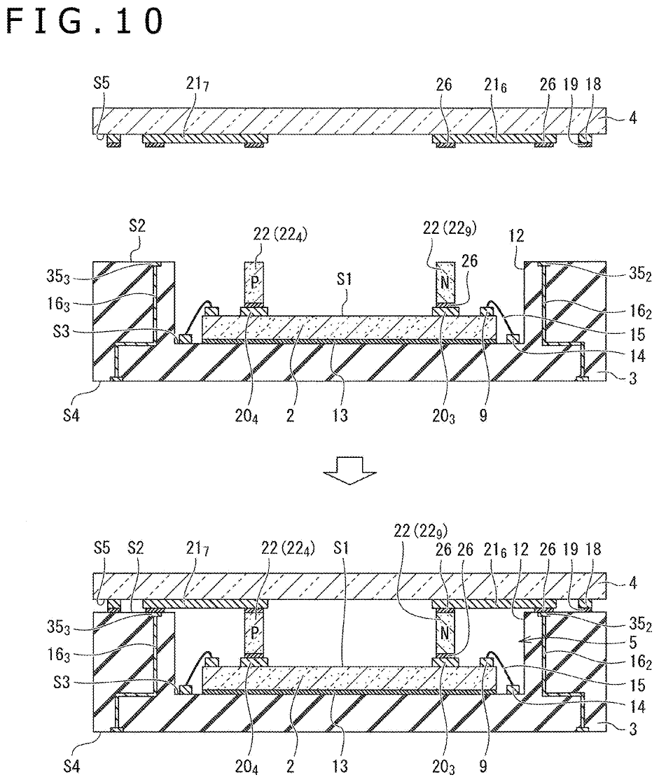

Subsequently, as depicted in FIG. 10, the position of the package substrate 3 in which the sensor chip 2 is housed and the position of the cover plate 4 to which the solders 19 and 26 are applied are aligned with each other, and the cover plate 4 is disposed on an upper surface S2 side of the package substrate 3. Subsequently, the solders 19 and 26 are melted by a reflow process to join the package substrate 3 and the cover plate 4 (the metal film 18), the second electrodes 21₁ to 21₈ and the thermoelectric elements 22₁ to 22₁₂, and the thermoelectric elements 22₁, 22₄, 22₉, and 22₁₂ and the second terminals 35₁ to 35₄ with each other. Accordingly, the thermoelectric element module 5 is formed between the sensor chip 2 and the cover plate 4, and the interior space of the recess portion 12 of the package substrate 3 is hermetically sealed. This process is performed in a dehumidified atmosphere such as dry air, nitrogen, or vacuum, so that the interior space of the recess portion 12 can be kept in a dehumidified atmosphere.

Subsequently, as depicted in FIG. 1, the heat dissipation mechanism 6 is disposed in the central portion of the lower surface S4 of the package substrate 3. Accordingly, the semiconductor apparatus 1 according to the first embodiment is completed.

As described above, in the semiconductor apparatus 1 according to the first embodiment, the thermoelectric element module 5 is disposed between the sensor chip 2 and the cover plate 4. Further, the thermoelectric element module 5 includes the first electrodes 20₁ to 20₆, which are formed in the third region 24 (the region on the edge side of the sensor chip 2 with respect to the pixel region 7) within the upper surface S1 (the surface facing the cover plate 4) of the sensor chip 2, the second electrodes 21₁ to 21₈, which are formed in the fourth region 25 (the region facing the third region 24) within the lower surface S5 (the surface facing the sensor chip 2) of the cover plate 4, and at least a pair of the thermoelectric elements 22₁ to 22₁₂, which are disposed between the first electrodes 20₁ to 20₆ and the second electrodes 21₁ to 21₈ and electrically connected to the first electrodes 20₁ to 20₆ and the second electrodes 21₁ to 21₈ so as to absorb heat from the sensor chip 2 and dissipate the heat to the cover plate 4. Accordingly, since the heat of the sensor chip 2 is directly transferred to the cover plate 4, the temperature of the cover plate 4 can be sufficiently raised and the capability to suppress condensation on the cover plate 4 can be improved. Further, since the heat is absorbed from the sensor chip 2, the sensor chip 2 can also be cooled.

Here, for example, in a case where a method of suppressing condensation on the cover plate 4 is employed as a hermetic package structure that seals the interior space of the recess portion 12, the degree of freedom of design and the degree of freedom of a package assembly method are reduced, and the downsizing of the semiconductor apparatus 1 becomes difficult due to the need for rigidity.

By contrast, in the semiconductor apparatus 1 according to the first embodiment, since the thermoelectric element module 5 can suppress condensation on the cover plate 4, there is no need for the hermetic package structure, and the degree of freedom of design and the degree of freedom of the package assembly method can be increased. Further, for example, the semiconductor apparatus 1 can be downsized compared to the case of employing the hermetic package structure because rigidity is not necessary.

Further, for example, in a case where a method of heating the cover plate 4 is employed as a structure in which a colorless transparent conductive thin film is disposed on the entire lower surface S5 of the cover plate 4, there is a possibility that light that passes through the conductive thin film forms an image due to a defect size of the conductive thin film, causing an image defect in an image obtained with the sensor chip 2. Furthermore, there is also a possibility that a decrease in light transmittance or a change in spectral characteristics occurs.

By contrast, in the semiconductor apparatus 1 according to the first embodiment, the second electrodes 21₁ to 21₈ are disposed within the fourth region 25, that is, at a position through which light toward the pixel region 7 does not pass. Therefore, it is possible to prevent an image defect due to image formation of light, a decrease in light transmittance, and a change in spectral characteristics.

### 1-3 Modifications

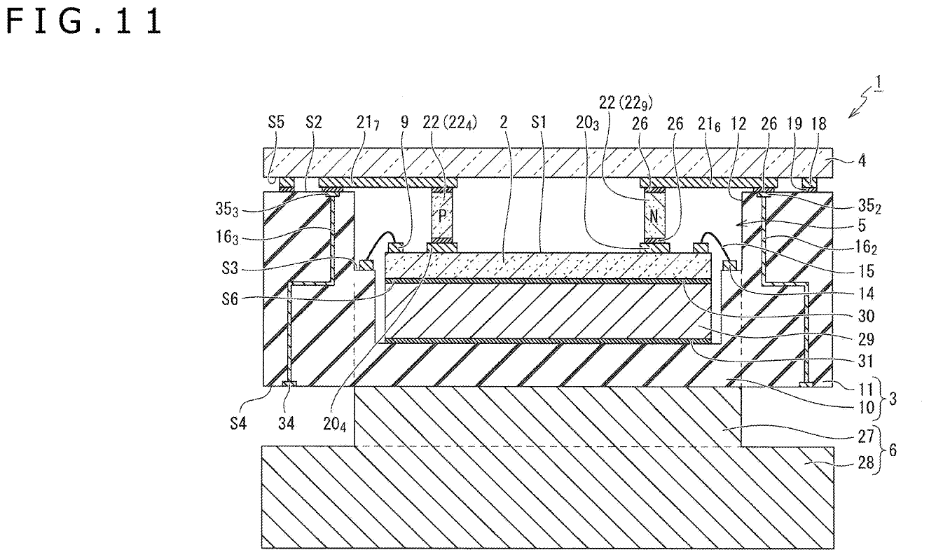

(1) It is noted that although an example in which the sensor chip 2 is bonded to the bottom surface S3 of the recess portion 12 has been described in the first embodiment, other configurations may also be employed. As depicted in FIG. 11, a configuration may also be, for example, such that a Peltier element 29, which absorbs heat from the sensor chip 2 and dissipates the heat to the package substrate 3, is provided between the sensor chip 2 and the bottom surface S3 of the recess portion 12. For example, in order to cover the entire surface (hereinafter also referred to as a “lower surface S6”) of the sensor chip 2 on a bottom surface S3 side of the recess portion 12, a Peltier element 29 that is the same as or slightly larger than the lower surface S6 is employed as the Peltier element 29. The Peltier element 53 is disposed such that a heat-absorbing surface faces a lower surface S6 side of the sensor chip 2 and a heat-dissipating surface faces the bottom surface S3 side of the recess portion 12. Accordingly, energizing the Peltier element 29 can transfer the heat of the sensor chip 2 to the package substrate 3, thereby improving the cooling performance of the sensor chip 2. The bottom surface S3 of the recess portion 12 and the Peltier element 29, and the Peltier element 29 and the sensor chip 2 are bonded to each other by adhesives 30 and 31.

Here, for example, in a case where a structure in which a sensor chip of a SWIR image sensor is used as the sensor chip 2 is employed, an image defect is likely to occur due to the heat of the sensor chip 2.

By contrast, in the semiconductor apparatus 1 according to the present modification, since the sensor chip 2 can be cooled by the Peltier element 29, the sensor chip 2 can be kept at a predetermined temperature or lower and an image defect caused by heat can be suppressed. However, in a case where the Peltier element 29 is disposed inside the recess portion 12, a new problem occurs such that condensation is likely to occur on the cover plate 4 due to repeated heating and cooling inside the recess portion 12.

To address this new problem, the semiconductor apparatus 1 according to the present modification heats the cover plate 4 with the thermoelectric element module 5 to further suppress condensation on the cover plate 4. This allows more appropriate images to be obtained from the SWIR image sensor.

The capability to suppress condensation on the cover plate 4 of the semiconductor apparatus 1 according to the present modification is considered.

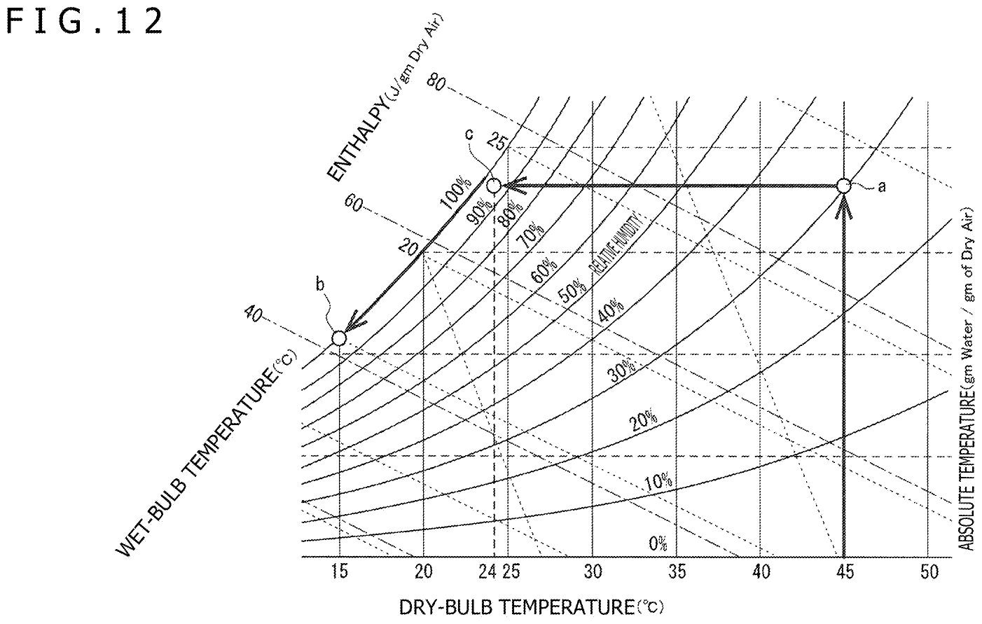

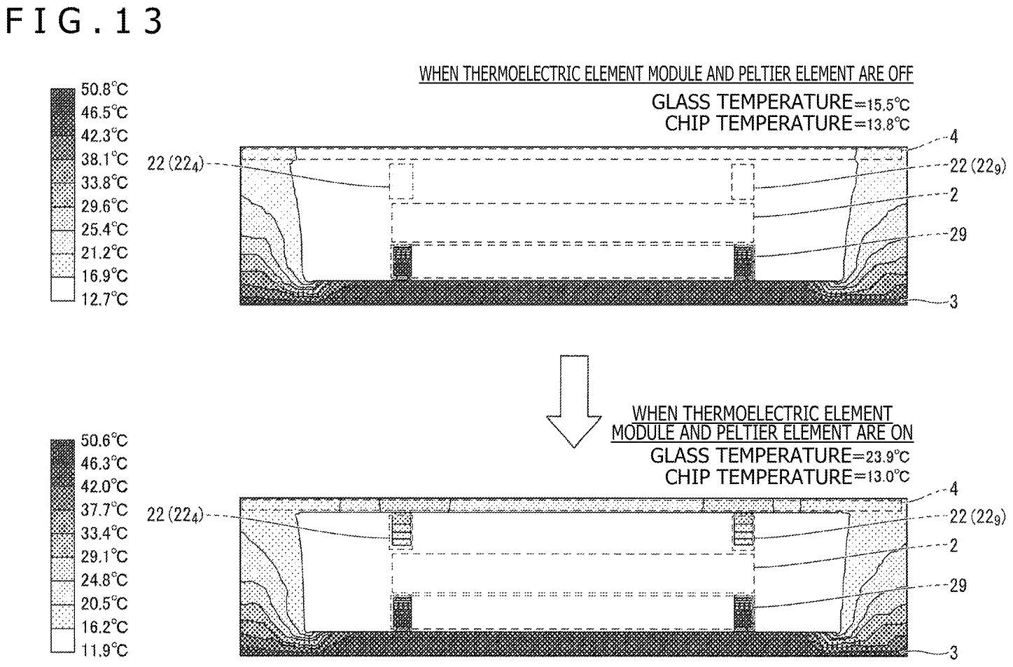

First, for example, assume that the temperature and relative humidity of the use environment of the semiconductor apparatus 1 are 45° C. and 30%, respectively, as depicted at a point a of FIG. 12. FIG. 12 is a diagram depicting a psychrometric chart at an atmospheric pressure of 101.325 kPa. Here, assume that the Peltier element 29 starts to be driven and the temperature of the sensor chip 2 becomes 13° C. and the temperature of the cover plate 4 becomes 15° C. Then, as depicted at a point b of FIG. 12, condensation occurs on the cover plate 4 since the relative humidity on a surface of the cover plate 4 reaches 100% in the psychrometric chart. Therefore, in order to suppress the occurrence of condensation on the cover plate 4, the temperature of the cover plate 4 needs to be increased to a temperature (e.g., 24° C.) where the relative humidity becomes less than 100%, as depicted at a point c of FIG. 12.

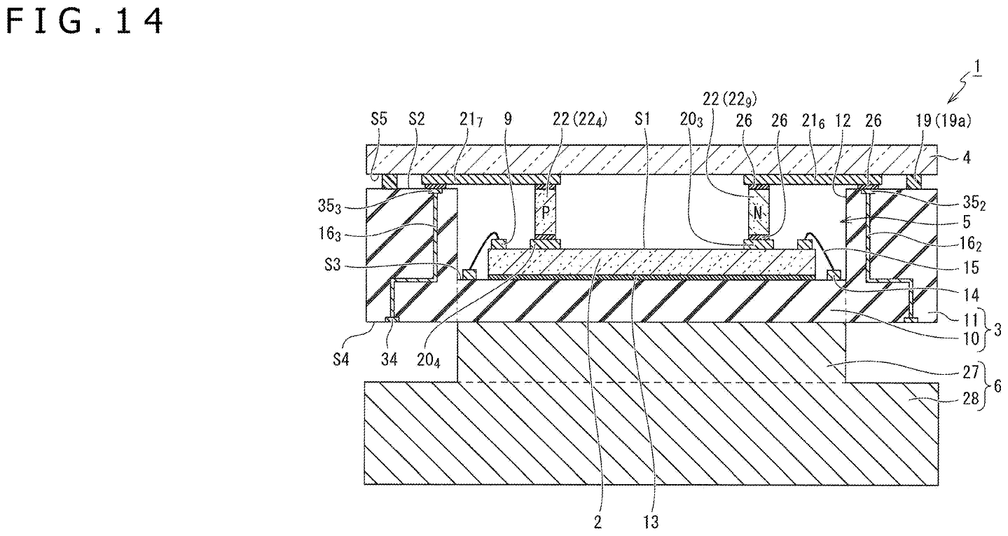

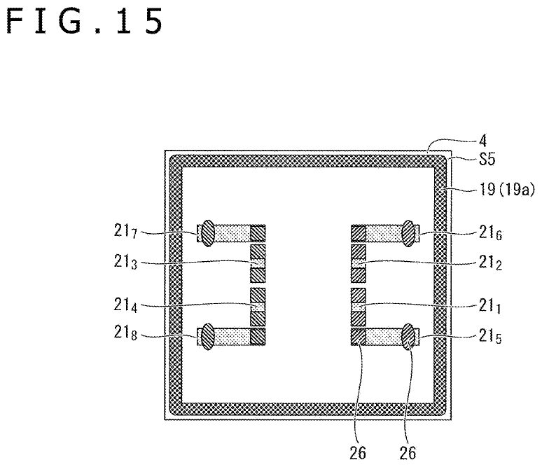

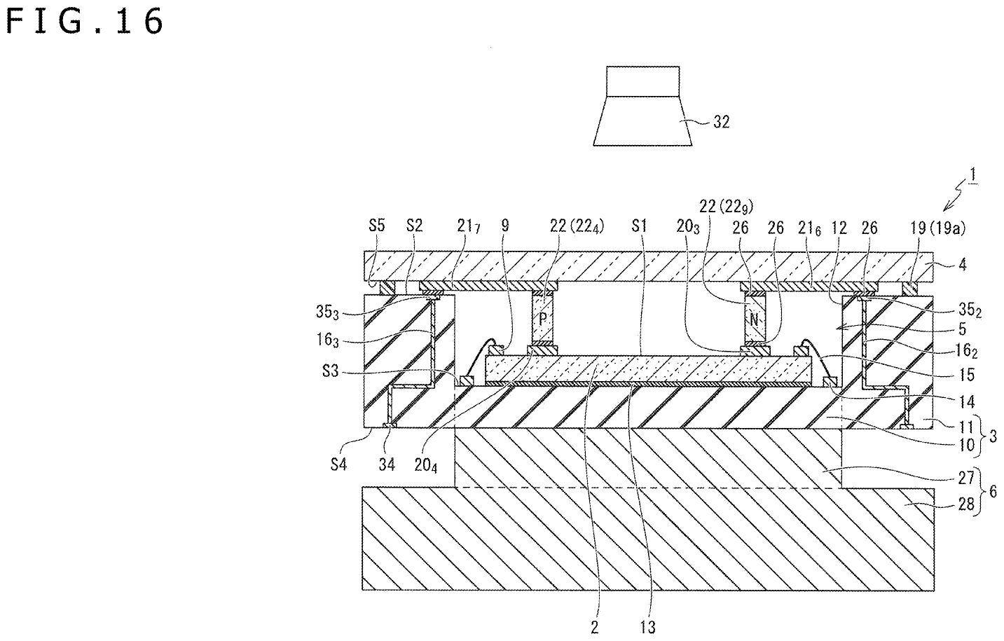

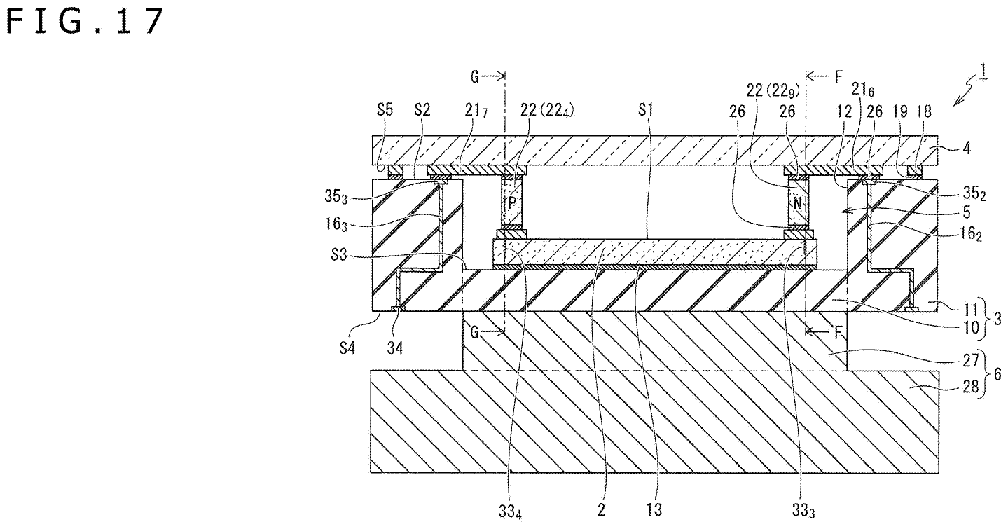

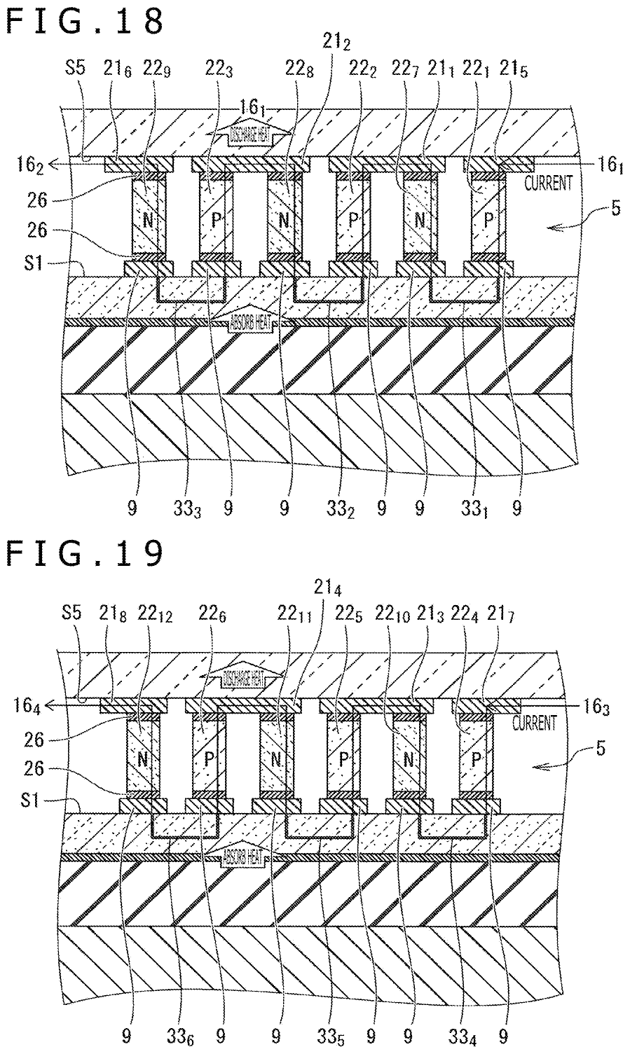

By contrast, with the semiconductor apparatus 1 according to the present modification, it was able to be confirmed by simulation that operating the thermoelectric element module 5 and heating the cover plate 4 can raise the temperature of the cover plate 4 to around 24° C., as depicted in FIG. 13. FIG. 13 is a diagram depicting a simulation result before and after the operation of the thermoelectric element module 5. In FIG. 13, the temperature of the cover plate 4 changes from 15.5° C. to 23.9° C. before and after the operation of the thermoelectric element module 5. Therefore, it was able to be confirmed that the Peltier element 29 has the capability to suppress condensation that occurs due to a decrease in the temperature of the interior space of the recess portion 12 (the temperature inside the package) when the Peltier element 29 is driven. In FIG. 13, the configuration of the semiconductor apparatus 1 is partially simplified for simulation purposes.
(2) Further, although an example in which a solder is used as the material for the sealing member 19 has been described in the first embodiment, other configurations can also be employed. For example, as depicted in FIG. 14, a resin may also be used. For example, an ultraviolet curable resin or an epoxy resin can be employed as the resin. In a case where a resin 19a is used as the material for the sealing member 19, the metal film 18 is omitted, as depicted in FIG. 14. That is, as depicted in FIG. 15, in the glass manufacturing flow, the formation of the metal film 18 is omitted in the process depicted in FIG. 7 in which the cover plate 4 is subjected to copper plating. Further, in the process of applying the solders 19 and 26 to the cover plate 4 depicted in FIG. 7, the resin 19a is applied as the material for the sealing member 19. FIG. 15 exemplifies a case where an ultraviolet curable resin is applied. Then, as depicted in FIG. 16, the ultraviolet curable resin is irradiated with ultraviolet light 32 from the cover plate 4 side before the reflow process of the solders 26 depicted in FIG. 10, so that the ultraviolet curable resin is cured (UV-cured). UV curing of the ultraviolet curable resin hermetically seals the interior space of the recess portion 12 in which the sensor chip 2 is disposed. In such a way, since the resin 19a, that is, an insulative material, is used as the material for the sealing member 19 in the present modification, it is possible to prevent electrode shorts due to contact between the solders 26, which are used when the second electrodes 21₅ to 21₈ are connected to the second terminals 35₁ to 35₄, and the sealing member 19. Further, since a resin generally has a low thermal conductivity, using a resin as the material for the sealing member 19 can prevent the heat of the cover plate 4 from escaping to the package substrate 3 via the sealing member 19 and suppress a decrease in the temperature of the cover plate 4.
(3) Further, although an example in which the first electrodes 20₁ to 20₆ are formed in the third region 24 (the region on the central side with respect to the region of the bonding pads 9) of the upper surface S1 of the sensor chip 2 has been described in the first embodiment, other configurations can also be employed. For example, as depicted in FIGS. 17, 18, and 19, the bonding pads 9 included in the sensor chip 2 may also be used as the first electrodes 20₁ to 20₆. FIG. 18 is a view depicting a cross-sectional configuration of the thermoelectric element module 5 in a case where the thermoelectric element module 5 is taken along line F-F of FIG. 17. Further, FIG. 19 is a view depicting a cross-sectional configuration of the thermoelectric element module 5 in a case where the thermoelectric element module 5 is taken along line G-G of FIG. 17. FIGS. 18 and 19 exemplify a case where each of the thermoelectric elements 22₁ to 22₁₂ is connected to a corresponding one of the bonding pads 9. Further, the bonding pads 9 used as the first electrodes 20₁ to 20₆ are pads that are connected to wirings 33₁, 33₂, 33₃, 33₄, 33₅, and 33₆ inside the sensor chip 2.

As depicted in FIG. 18, the wirings 33₁, 33₂, and 33₃ are connected to the respective bonding pads 9 such that the end portions of the adjacent P-type thermoelectric element 22₁ and N-type thermoelectric element 22₇, the adjacent P-type thermoelectric element 22₂ and N-type thermoelectric element 22₈, the adjacent P-type thermoelectric element 22₃ and N-type thermoelectric element 22₉ on the sensor chip 2 side are connected to each other. Further, as depicted in FIG. 19, the wirings 33₄, 33₅, and 33₆ are connected to the respective bonding pads 9 such that the end portions of the adjacent P-type thermoelectric element 22₄ and N-type thermoelectric element 22₁₀, the adjacent P-type thermoelectric element 22₅ and N-type thermoelectric element 22₁₁, and the adjacent P-type thermoelectric element 22₆ and N-type thermoelectric element 22₁₂ on the sensor chip 2 side are connected to each other. In such a way, in the present modification, since the bonding pads 9 initially included in the sensor chip 2 are used as the first electrodes 20₁ to 20₆, the process of forming the first electrodes 20₁ to 20₆ by copper plating or the like can be omitted.

It is noted that although an example in which each of the thermoelectric elements 22₁ to 22₁₂ is connected to a corresponding one of the bonding pads 9 has been described in the present modification, a configuration may also be, for example, such that the bonding pads 9 are increased in size and a pair of the thermoelectric elements 22₁ to 22₁₂ is connected to one bonding pad 9.

### 2. Second Embodiment: Semiconductor Apparatus

### 2-1 Overall Configuration of Semiconductor Apparatus

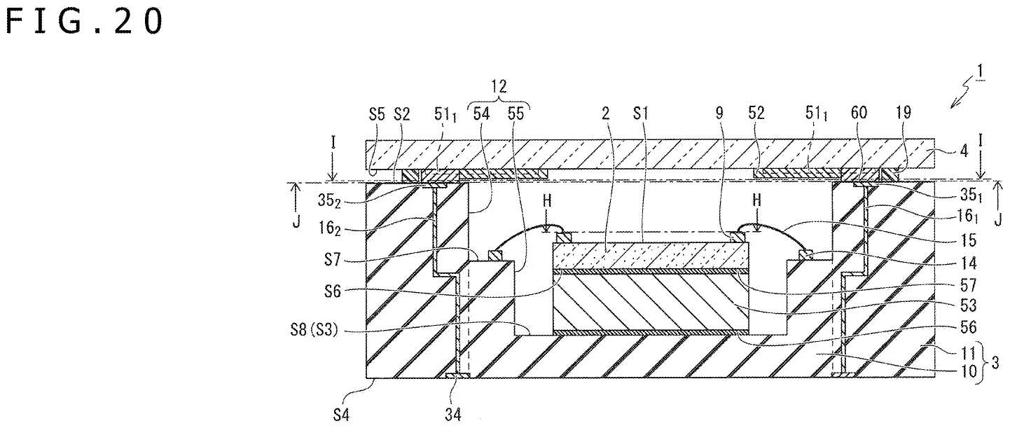

Next, the semiconductor apparatus 1 according to a second embodiment of the present disclosure will be described. FIG. 20 is a view depicting an overall schematic configuration of the semiconductor apparatus 1 according to the second embodiment. In the second embodiment, portions corresponding to the first embodiment are denoted with the same reference signs and redundant description is omitted.

As depicted in FIG. 20, the second embodiment differs from the first embodiment in that the thermoelectric element module 5 and the heat dissipation mechanism 6 depicted in FIG. 1 are omitted, and resistive heating elements 51₁ and 51₂, a heat insulating member 52, and a Peltier element 53 are provided. That is, the semiconductor apparatus 1 according to the second embodiment includes the sensor chip 2, the package substrate 3, the cover plate 4, the resistive heating elements 51₁ and 51₂, the heat insulating member 52, and the Peltier element 53.

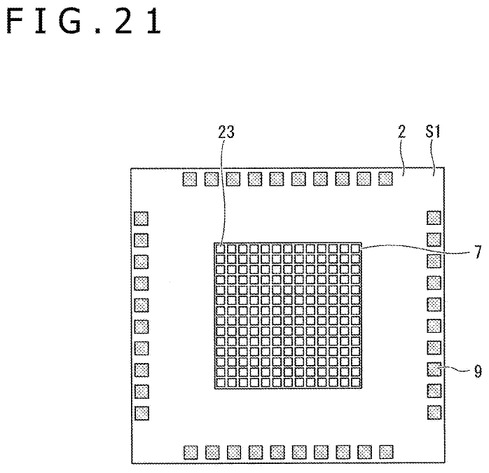

Here, as depicted in FIGS. 20 and 21, the first electrodes 20₁ to 20₆ depicted in FIGS. 1 and 2 are omitted on the upper surface S1 of the sensor chip 2 according to the second embodiment. FIG. 21 is a view depicting a planar configuration of the sensor chip 2 in a case where the sensor chip 2 is viewed from a line H-H side of FIG. 20.

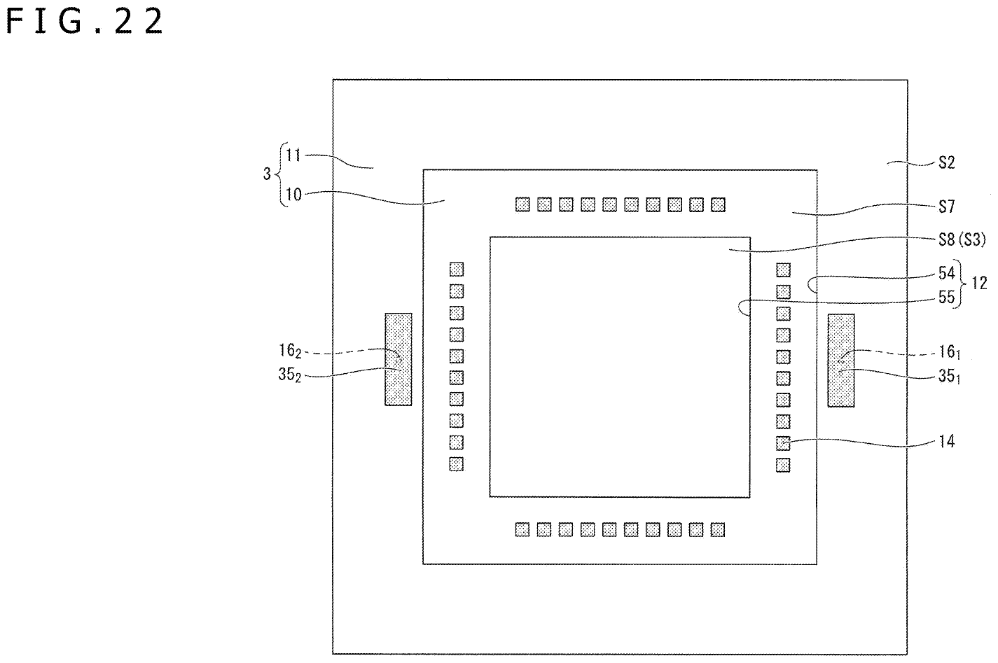

Further, as depicted in FIGS. 20 and 22, the recess portion 12 of the package substrate 3 includes a first recess portion 54, which is formed in a central portion of the upper surface S2 of the package substrate 3, and a second recess portion 55, which is formed in a central portion of a bottom surface S7 of the first recess portion 54. FIG. 22 exemplifies a case where opening portions of the first recess portion 54 and the second recess portion 55 have a rectangular shape in a planar view. FIG. 22 is a view depicting a planar configuration of the package substrate 3 in a case where the package substrate 3 is viewed from a line I-I side of FIG. 20.

Further, the Peltier element 53 and the sensor chip 2 are disposed in this order in a central portion of a bottom surface S8 of the second recess portion 55. Accordingly, the Peltier element 53 and the sensor chip 2 are housed in the interior space of the recess portion 12 of the package substrate 3. The bottom surface S8 of the second recess portion 55 and the Peltier element 53, and the Peltier element 53 and the sensor chip 2 are bonded to each other with adhesives 56 and 57, respectively.

Further, the bonding pads 14 on the package substrate 3 are formed in a region that is within the bottom surface S7 of the first recess portion 54 and that is located around the opening portion of the second recess portion 55.

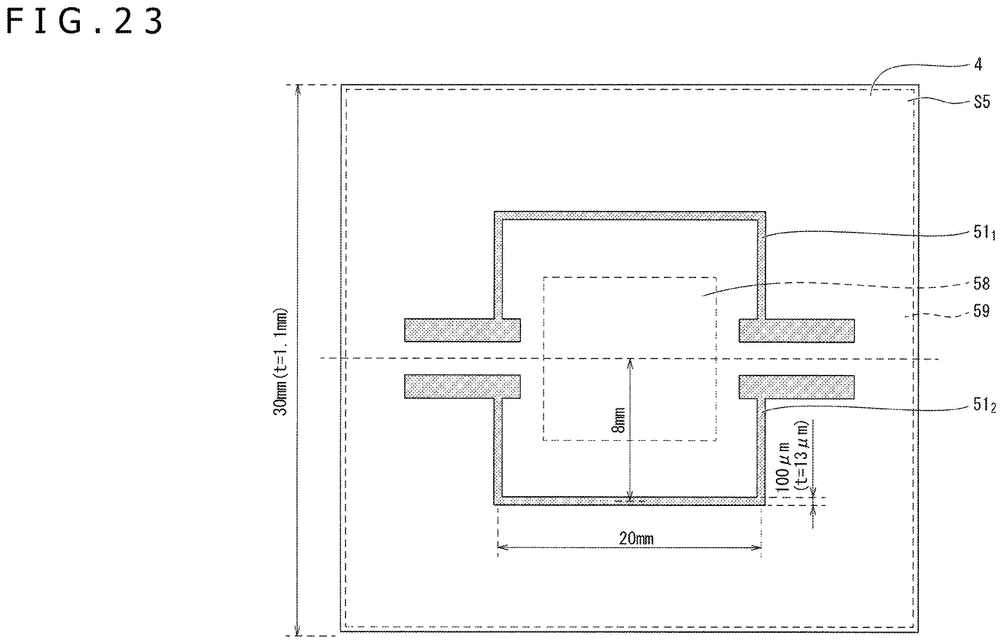

Further, among the interior wirings 16₁ to 16₄ depicted in FIG. 3, the interior wirings 16₃ and 16₄ are omitted and the interior wirings 16₁ and 16₂ remain as depicted in FIG. 22. FIG. 22 exemplifies a case where in a planar view, the interior wiring 16₁ is disposed on a right side of the recess portion 12 and the interior wiring 16₂ is disposed on a left side of the recess portion 12. Further, the interior wiring 16₁ is connected to end portions of the resistive heating elements 51₁ and 51₂ depicted in FIG. 23 via the second terminal 35₁, and the interior wiring 16₂ is connected to opposite end portions of the resistive heating elements 51₁ and 51₂ depicted in FIG. 23 via the second terminal 35₂. This allows the interior wirings 16₁ to 16₄ to energize the resistive heating elements 51₁ and 51₂.

Further, the second electrodes 21₁ to 21₈ depicted in FIGS. 1 and 4 are omitted on the lower surface S5 of the cover plate 4, as depicted in FIGS. 20 and 23. FIG. 23 is a view depicting planar configurations of the cover plate 4, the resistive heating elements 51₁ and 51₂, and so forth in a case where the cover plate 4, the resistive heating elements 51₁ and 51₂, and so forth are viewed from a line J-J side of FIG. 20.

Further, the sealing member 19 between the cover plate 4 and the package substrate 3 includes a resin (sealing resin), as depicted in FIG. 20. Accordingly, since a resin, that is, an insulative material, is used as the material for the sealing member 19, even if silver pastes 60, which are used when the resistive heating elements 51₁ and 51₂ are connected to the second terminals 35₁ and 35₂, and the sealing member 19 come into contact with each other, electrode shorts do not occur. Further, since a resin generally has a low thermal conductivity, using a resin as the material for the sealing member 19 can prevent the heat of the cover plate 4 from escaping to the package substrate 3 via the sealing member 19 and suppress a decrease in the temperature of the cover plate 4. For example, a resin having a low thermal conductivity can be employed as the resin. One example is an epoxy resin.

The resistive heating elements 51₁ and 51₂ are thin-film heating elements that generate heat when energized. As depicted in FIG. 23, the resistive heating elements 51₁ and 51₂ are formed in a region (i.e., a region excluding a fifth region 58; hereinafter also referred to as a “sixth region 59”) that is within the lower surface S5 of the cover plate 4 and that is on an edge side of the cover plate 4 with respect to a region (hereinafter, the “fifth region 58”) facing the pixel region 7 of the sensor chip 2. That is, the resistive heating elements 51₁ and 51₂ are formed in the region through which light toward the pixel region 7 does not pass. Each of the resistive heating elements 51₁ and 51₂ is formed along an outer periphery of the fifth region 58. FIG. 23 exemplifies a case where, in a planar view, the resistive heating element 51₁ is disposed so as to be an inverted U-shaped wiring that surrounds an upper half of the fifth region 58, and the resistive heating element 51₂ is disposed so as to be a U-shaped wiring that surrounds a lower half of the fifth region 58. For example, a conductive material can be employed as a material for the resistive heating elements 51₁ and 51₂. One example is a silver paste.

Further, the end portions of the resistive heating elements 51₁ and 51₂ extend to the edge side of the cover plate 4 so as to overlap with the second terminals 35₁ and 35₂ in a planar view. The end portions of the resistive heating elements 51₁ and 51₂ and the second terminals 35₁ and 35₂ are electrically connected to each other by the silver pastes 60. Further, the silver pastes 60 also function as adhesives to bond the cover plate 4 and the package substrate 3 to each other. This makes it possible to realize a simple assembly structure that only requires bonding with the silver pastes 60.

With such a configuration, for example, applying a voltage to the interior wirings 16₁ and 16₂ can cause current flowing from one side of the interior wirings 16₁ and 16₂ to the other side to pass through (energize) each of the resistive heating elements 51₁ and 51₂. Then, energizing the resistive heating elements 51₁ and 51₂ can cause the resistive heating elements 51₁ and 51₂ to generate heat, thereby heating the cover plate 4. Such a configuration can sufficiently raise the temperature of the cover plate 4 and suppress condensation on the cover plate 4. The heating of the cover plate 4 using the resistive heating elements 51₁ and 51₂ is performed synchronously with the driving of the Peltier element 53.

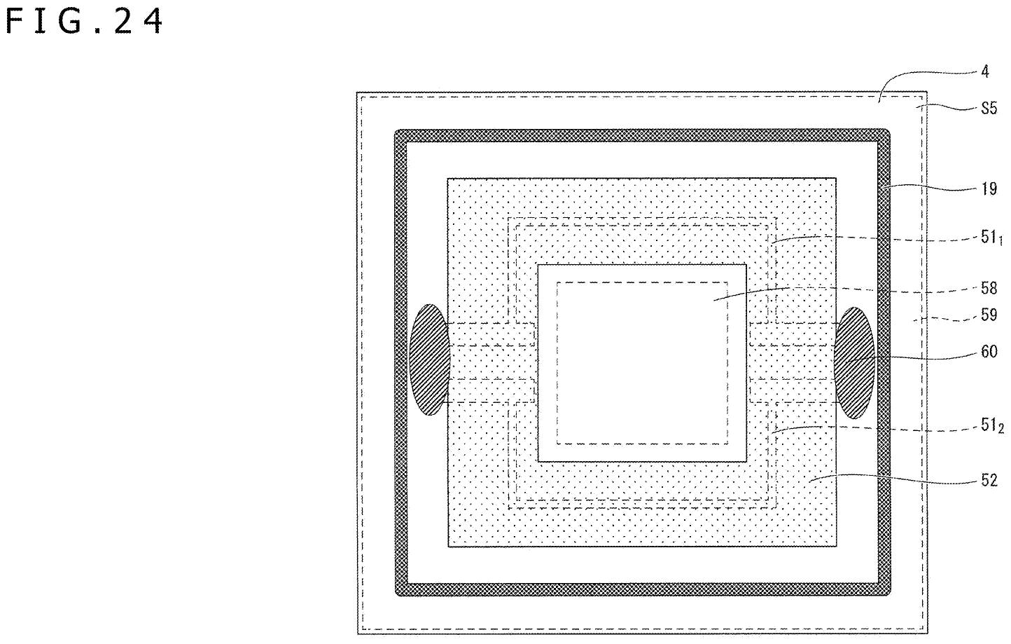

The heat insulating member 52 is a heat insulating film for blocking the radiation heat of the resistive heating elements 51₁ and 51₂. As depicted in FIG. 24, the heat insulating member 52 is formed in the sixth region 59 (the region excluding the fifth region 58) of the lower surface S5 of the cover plate 4. That is, the heat insulating member 52 is formed at a position where light toward the pixel region 7 does not pass through. The heat insulating member 52 continuously covers the resistive heating elements 51₁ and 51₂ (excluding the end portions thereof) and their surroundings. Accordingly, the heat insulating member 52 can block the radiation heat from the resistive heating elements 51₁ and 51₂ to the sensor chip 2, thereby suppressing the rise of the temperature of the sensor chip 2 that would otherwise occur due to the radiation heat and, moreover, efficiently heating the entire cover plate 4.

FIG. 24 is a view depicting planar configurations of the cover plate 4, the resistive heating elements 51₁ and 51₂, and so forth in a case where the cover plate 4, the resistive heating elements 51₁ and 51₂, and so forth are viewed from a line J-J side of FIG. 20, and including the heat insulating member 52 and the silver pastes 60 on the lower surface S5 of the cover plate 4. FIG. 24 exemplifies a case where the heat insulating member 52 is disposed so as to have a hollow rectangular shape covering the resistive heating elements 51₁ and 51₂ in a planar view. For example, a heat insulating material can be employed as a material for the heat insulating member 52. One example is an epoxy resin.

Further, for example, black can be employed as the color of the heat insulating member 52. By employing black, light reflected from members (such as the bonding wires 15) around the sensor chip 2 can be absorbed, re-reflection of the reflected light to the pixel region 7 can be suppressed, and the generation of a flare can be suppressed.

The Peltier element 53 is an element for cooling the sensor chip 2. The Peltier element 53 is disposed such that the heat-absorbing surface faces the lower surface S6 side of the sensor chip 2 and the heat-dissipating surface faces a bottom surface S8 side of the second recess portion 55. This allows the Peltier element 53 to absorb heat from the sensor chip 2 and dissipate the heat to the package substrate 3 when energized.

### 2-2 Method of Manufacturing Semiconductor Apparatus

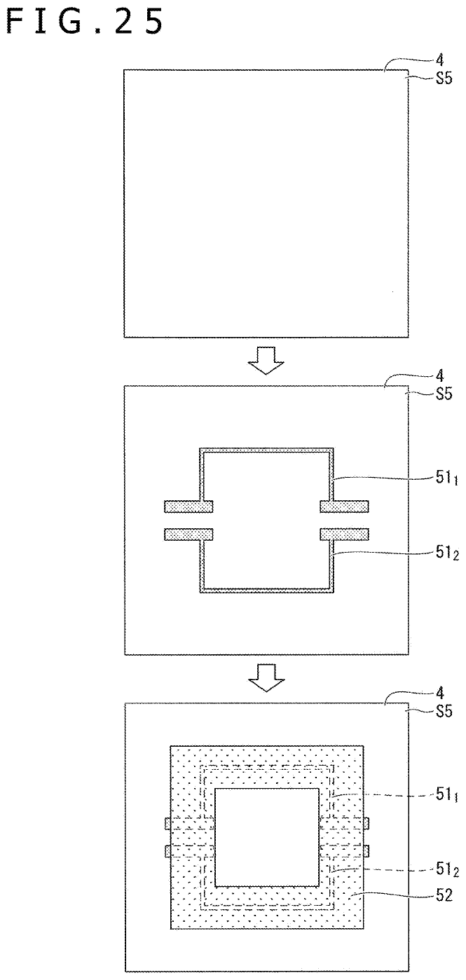

Next, a method of manufacturing the semiconductor apparatus 1 according to the second embodiment will be described. FIGS. 25, 26, 27, and 28 are views depicting the method of manufacturing the semiconductor apparatus 1 according to the second embodiment.

In the manufacturing method according to the second embodiment, the glass manufacturing flow and the package assembly flow are performed in this order. The chip manufacturing flow depicted in FIG. 8 is omitted. First, the glass manufacturing flow is performed. As depicted in FIG. 25, the cover plate 4 is prepared and a conductive material (e.g., a silver paste) is printed on one surface (the lower surface S5) of the prepared cover plate 4 to form the resistive heating elements 51₁ and 51₂. After that, thermal curing for heating and curing the conductive material is performed. Subsequently, a heat insulating material (e.g., an epoxy resin) is printed on each of the formed resistive heating elements 51₁ and 51₂ to form the heat insulating member 52. After that, thermal curing for heating and curing the heat insulating material is performed.

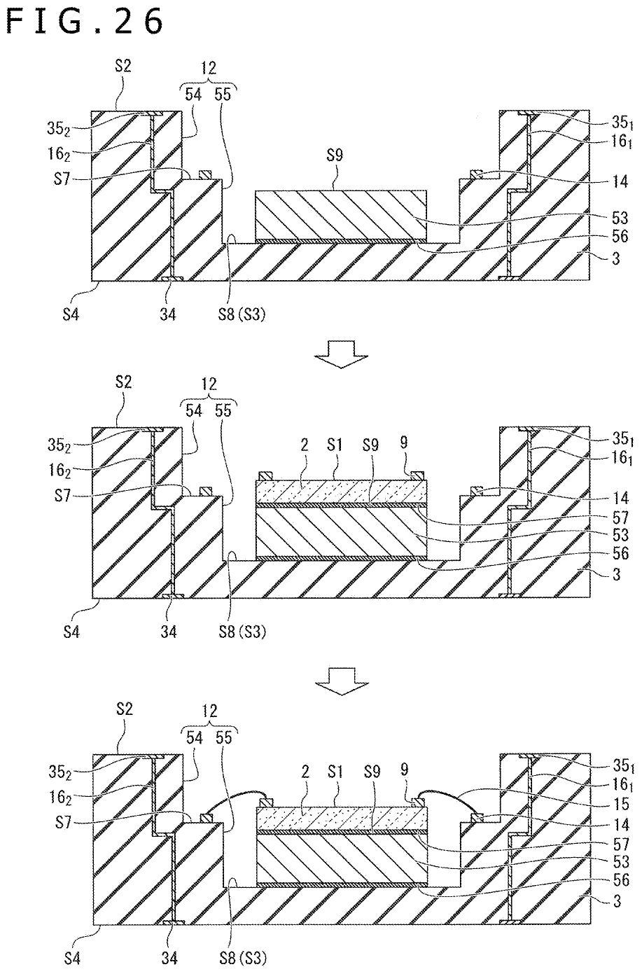

Subsequently, the package assembly flow is performed to bond the Peltier element 53 to the bottom surface S8 of the second recess portion 55 of the package substrate 3 via the adhesive 56, as depicted in FIG. 26. After that, thermal curing for heating and curing the adhesive 56 is performed. Subsequently, the sensor chip 2 is bonded to an upper surface S9 of the bonded Peltier element 53 via the adhesive 57. After that, thermal curing for heating and curing the adhesive 57 is performed. Subsequently, the bonding pads 9 on the sensor chip 2 and the bonding pads 14 on the package substrate 3 are electrically connected to each other via the bonding wires 15. Accordingly, the sensor chip 2 and terminals (not depicted) formed on the lower surface S4 and so forth of the package substrate 3 are electrically connected to each other, and pixel signals of the sensor chip 2 can be output externally.

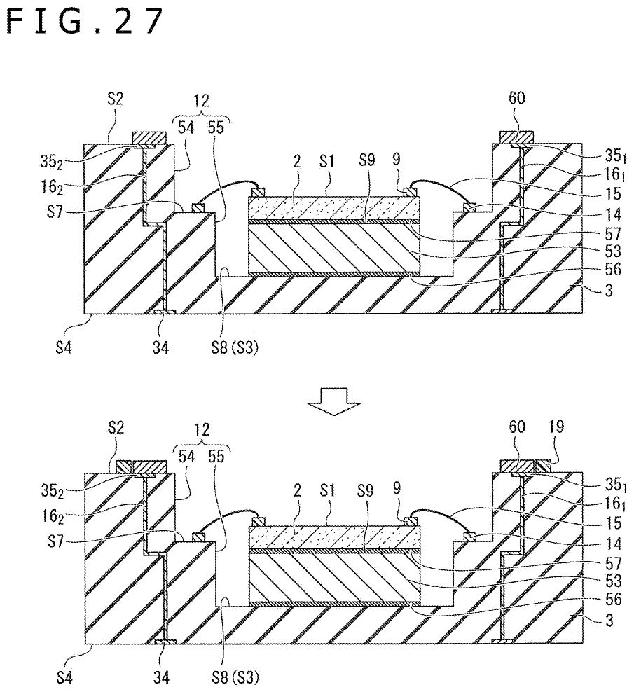

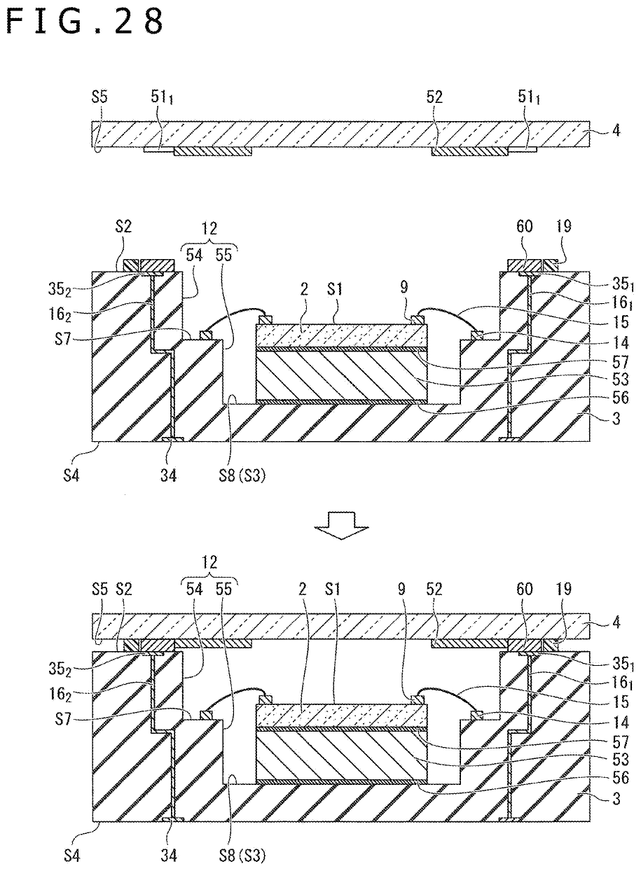

Subsequently, as depicted in FIG. 27, the silver pastes 60 are applied to the second terminals 35₁ and 35₂ of the package substrate 3. Subsequently, a sealing resin as the material for the sealing member 19 is applied to the upper surface S2 of the package substrate 3. Subsequently, as depicted in FIG. 28, the position of the package substrate 3 and the position of the cover plate 4 are aligned with each other, and the cover plate 4 on which the resistive heating elements 51₁ and 51₂ have been formed is disposed on the upper surface S2 side of the package substrate 3. Subsequently, thermal curing of the sealing resin and curing of the silver pastes 60 are performed to join the package substrate 3 and the cover plate 4, and the resistive heating elements 51₁ and 51₂ and the second terminals 35₁ and 35₂ with each other. Accordingly, the resistive heating elements 51₁ and 51₂ and the interior wirings 16₁ and 16₂ are electrically connected to each other, and the interior space of the recess portion 12 of the package substrate 3 is hermetically sealed. This process is performed in a dehumidified atmosphere such as dry air, nitrogen, or vacuum, so that the interior space of the recess portion 12 can be kept in a dehumidified atmosphere. Through this process, the semiconductor apparatus 1 according to the second embodiment is completed.

As described above, in the semiconductor apparatus 1 according to the second embodiment, the resistive heating elements 51₁ and 51₂ are disposed in the region (the sixth region 59 on the edge side of the cover plate 4) that is within the lower surface S5 (the surface facing the sensor chip 2) of the cover plate 4 and that excludes the region (the fifth region 58) facing the pixel region 7. Accordingly, passing the current through the resistive heating elements 51₁ and 51₂ can cause the resistive heating elements 51₁ and 51₂ to generate heat, thereby directly heating the cover plate 4. Therefore, the temperature of the cover plate 4 can be raised and the capability to suppress condensation on the cover plate 4 can be improved.

Here, for example, in a case where a method of suppressing condensation on the cover plate 4 is employed as a hermetic package structure that seals the interior space of the recess portion 12, the degree of freedom of design and the degree of freedom of the package assembly method are reduced, and the downsizing of the semiconductor apparatus 1 becomes difficult due to the need for rigidity.

By contrast, in the semiconductor apparatus 1 according to the second embodiment, since the resistive heating elements 51₁ and 51₂ can suppress condensation on the cover plate 4, there is no need for the hermetic package structure, and the degree of freedom of design and the degree of freedom of the package assembly method can be increased. Further, for example, the semiconductor apparatus 1 can be downsized compared to the case of employing the hermetic package structure because rigidity is not necessary.

Further, for example, in a case where a method of heating the cover plate 4 is employed as a structure in which a colorless transparent conductive thin film is disposed on the entire lower surface S5 of the cover plate 4, there is a possibility that light that passes through the conductive thin film forms an image due to a defect size of the conductive thin film, causing an image defect in an image obtained with the sensor chip 2. Furthermore, there is also a possibility that a decrease in light transmittance or a change in spectral characteristics occurs.

By contrast, in the semiconductor apparatus 1 according to the second embodiment, the resistive heating elements 51₁ and 51₂ and the heat insulating member 52 are disposed within the sixth region 59, that is, at the positions through which light toward the pixel region 7 does not pass. Therefore, it is possible to prevent an image defect due to image formation of light caused by the defect sizes of the resistive heating elements 51₁ and 51₂ and the heat insulating member 52. Further, it is possible to prevent a decrease in light transmittance or a change in spectral characteristics due to the resistive heating elements 51₁ and 51₂ and the heat insulating member 52. Further, the resistive heating elements 51₁ and 51₂ and the heat insulating member 52 do not need to be colorless and transparent. Therefore, the degree of freedom in material selection can be increased. For example, materials with high heating efficiency or materials with high insulating properties can be employed regardless of whether they are colored or colorless.

Further, for example, as described in the modification (1) of the first embodiment, in a case where a sensor chip of a SWIR image sensor is used as the sensor chip 2 and the Peltier element 53 is disposed inside the recess portion 12, a new problem occurs such that condensation is likely to be generated on the cover plate 4.

To address this new problem, the semiconductor apparatus 1 according to the second embodiment heats the cover plate 4 with the resistive heating elements 51₁ and 51₂ to suppress condensation on the cover plate 4. This allows more appropriate images to be obtained from the SWIR image sensor.

The feasibility of the semiconductor apparatus 1 according to the second embodiment is considered.

First, as with the modification (1) of the first embodiment, assume a case where when the temperature and relative humidity of the use environment are 45° C. and 30%, respectively, the Peltier element 29 starts to be driven and the temperature of the sensor chip 2 changes to 13° C. and the temperature of the cover plate 4 changes to 15° C. (refer to points a and b of FIG. 12). In this case, in order to suppress the occurrence of condensation on the cover plate 4, it is necessary to raise the temperature of the cover plate 4 to a temperature (24° C.) at which the relative humidity becomes less than 100%, as depicted at a point c of FIG. 12. In other words, the temperature of the cover plate 4 needs to be increased by 9° C.

Here, the amount of heat necessary to raise the temperature of the cover plate 4 by 9° C. is calculated on the basis of the glass heating temperature, the glass cross-sectional area, the distance to a heating point (a central portion of the cover plate 4), and the glass thermal conductivity as in an expression (1) below. In the expression (1) below, as depicted in FIG. 23, the calculation is performed, assuming that the length of one side of the cover plate 4 is 30 mm and the thickness thereof is 1.1 mm, the length of one side of each of the resistive heating elements 51₁ and 51₂ is 20 mm, the distance from each of the resistive heating elements 51₁ and 51₂ to the heating point is 8 mm, and the thermal conductivity of the cover plate 4 is 1.38 W/mK.

$$The necessary amount of heat = glass heating temperature \times \qquad ( 1 )$$

$$( glass cross - sectional area \div distance to heating point ) \times$$

$$glass thermal conductivity$$

$$= {9}^{°} C . \times ( 2.2 \times 1 {0}^{- 5} {m}^{2} \div 8 \times 1 {0}^{- 3} m ) \times 1.38 W / mK$$

$$= 34 mW$$

Further, the wiring resistance necessary to obtain this necessary amount of heat is calculated on the basis of the necessary amount of heat and the voltage applied to the resistive heating elements 51₁ and 51₂ as in an expression (2) below. In the expression (2) below, the calculation is performed, assuming that the voltage applied to the resistive heating elements 51₁ and 51₂ is 1 V.

$$Wiring resistance = voltage \div ( necessary amount of heat \div voltage ) \qquad ( 2 )$$

$$= 1 V \div ( 0.034 W \div 1 V )$$

$$= 29 Ω$$

Further, the wiring cross-sectional area necessary to obtain this wiring resistance is calculated on the basis of the wiring resistance, the specific resistance, and the wiring length (the length of one side of each of the resistive heating elements 51₁ and 51₂) as in an expression (3) below. In the expression (3) below, the calculation is performed, assuming that the specific resistance of the silver paste is 2×10⁻⁴Ω·cm and the length of one side of each of the resistive heating elements 51₁ and 51₂ is 20 mm (refer to FIG. 23).

$$Wiring cross - sectional area = \qquad ( 3 )$$

$$specific resistance \times wiring length / wiring resistance$$

$$= 2 \times 1 {0}^{- 4} Ω \cdot cm \times 2 cm \div 29 Ω$$

$$= 1.3 \times 1 {0}^{- 3} {mm}^{2}$$

Such a wiring cross-sectional area of 1.3×10⁻³ mm² can be realized by, for example, making the width and thickness of the resistive heating elements 51₁ and 51₂ 100 μm and 13 μm, respectively, as depicted in FIG. 23. Hence, it was able to be confirmed that the semiconductor apparatus 1 according to the second embodiment has no feasibility problems.

### 2-3 Modifications

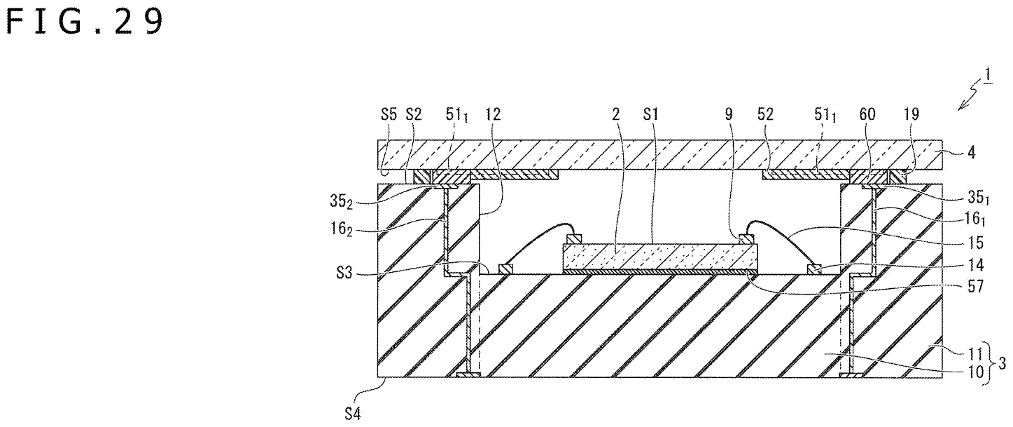

(1) It is noted that although an example in which the Peltier element 53 is disposed between the sensor chip 2 and the bottom surface S3 (the bottom surface S8 of the second recess portion 55) of the recess portion 12 of the package substrate 3 has been described in the second embodiment, other configurations can also be employed. For example, as depicted in FIG. 29, a configuration may also be, for example, such that the Peltier element 53 is omitted and the sensor chip 2 is directly bonded to the bottom surface S3 of the recess portion 12.
(2) Further, although an example in which a resin is used as the material for the sealing member 19 has been described in the second embodiment, other configurations can be employed. For example, a silver paste may also be used. In a case where a silver paste is used as the material for the sealing member 19, sealing using the sealing member 19 can also be performed in the process for joining the resistive heating elements 51₁ and 51₂ and the second terminals 35₁ and 35₂ with each other.
(3) Further, a configuration may also be, for example, such that the heat dissipation mechanism 6 (such as a heat sink) depicted in FIG. 1 is disposed on the lower surface S4 of the package substrate 3, as with the semiconductor apparatus 1 according to the first embodiment.

### 3. Electronic Device

The technology (the present technology) according to the present disclosure may also be applied to various electronic devices.

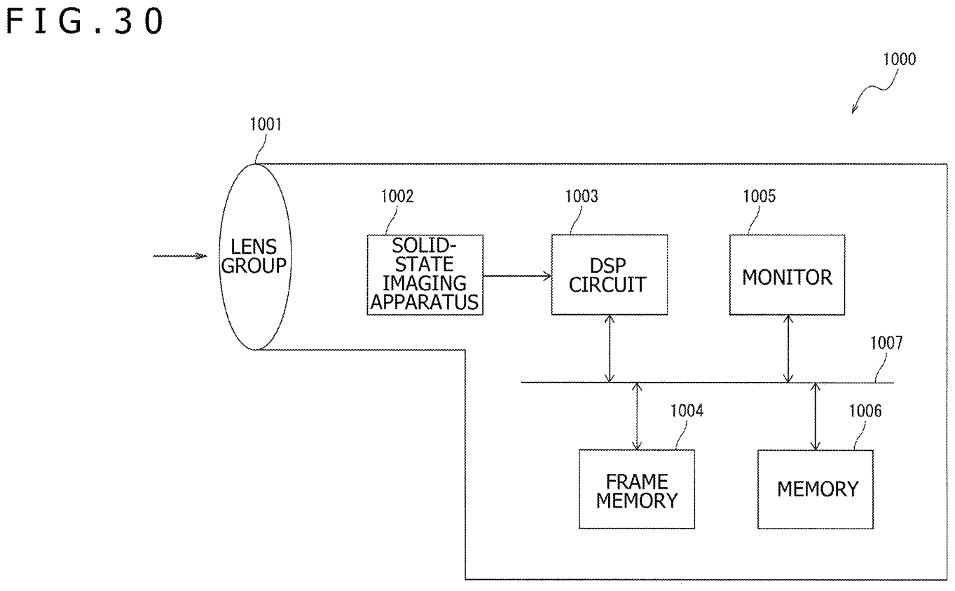

FIG. 30 is a diagram depicting an example of a schematic configuration of an imaging apparatus 1000 (e.g., a video camera or a digital still camera) as an electronic device to which the present technology is applied. As depicted in FIG. 30, the imaging apparatus 1000 includes a lens group 1001, a semiconductor apparatus 1002, a DSP (Digital Signal Processor) circuit 1003, a frame memory 1004, a monitor 1005, and a memory 1006. The DSP circuit 1003, the frame memory 1004, the monitor 1005, and the memory 1006 are connected to each other via a bus line 1007.

The lens group 1001 guides light (image light) incident from a subject to the semiconductor apparatus 1002 and forms an image on a light-receiving surface (pixel region) of the semiconductor apparatus 1002.

The semiconductor apparatus 1002 includes the semiconductor apparatus 1 according to the first embodiment described above. The semiconductor apparatus 1002 converts the amount of incident light that has been formed as an image on the light-receiving surface by the lens group 1001 into electrical signals in pixel units, and supplies the electrical signals to the DSP circuit 1003 as pixel signals.

The DSP circuit 1003 performs predetermined image processing on the pixel signals supplied from the semiconductor apparatus 1002. Then, the DSP circuit 1003 supplies the image signals subjected to image processing to the frame memory 1004 in frame units and causes the frame memory 1004 to temporarily store the image signals.

The monitor 1005 includes a panel-type display apparatus such as a liquid crystal panel or an organic EL (Electro Luminescence) panel, for example. The monitor 1005 displays an image (e.g., a moving image) of a subject on the basis of the pixel signals temporarily stored in the frame memory 1004 in frame units.

The memory 1006 includes a DVD, a flash memory, or the like. The memory 1006 reads out and records, thereon, the pixel signals temporarily stored in the frame memory 1004 in frame units.

It is noted that the electronic device to which the present technology can be applied is not limited to the imaging apparatus 1000. The present technology can also be applied to other electronic devices. Further, although a configuration using the semiconductor apparatus 1 according to the first embodiment as the semiconductor apparatus 1002 has been employed, other configurations can also be employed. For example, a configuration using another reaction apparatus such as the semiconductor apparatus 1 according to the second embodiment or the semiconductor apparatus 1 according to the modifications of the first and second embodiments to which the present technology is applied may also be employed.

It is noted that the present technology can also have the following configurations.

(1)

A semiconductor apparatus including:
a package substrate having a recess portion on a first surface;
a sensor chip disposed inside the recess portion and having a pixel region in which photoelectric conversion sections are arranged;
a transparent cover plate disposed on the first surface and covering an opening portion of the recess portion; and
a thermoelectric element module disposed between the sensor chip and the cover plate, in which
the thermoelectric element module includes
   a first electrode formed in a region within a surface of the sensor chip facing the cover plate, the region being on an edge side of the sensor chip with respect to the pixel region,
   a second electrode formed in a region within a surface of the cover plate facing the sensor chip, the region facing the region on the edge side, and
   at least a pair of thermoelectric elements disposed between the first and second electrodes and configured to be electrically connected to the first and second electrodes so as to absorb heat from the sensor chip and dissipate the heat to the cover plate.
      (2)

The semiconductor apparatus according to (1) above, further including:
a Peltier element disposed between the sensor chip and a bottom surface of the recess portion and configured to absorb heat from the sensor chip and dissipate the heat to the package substrate.
   (3)

The semiconductor apparatus according to (1) or (2) above, further including:
a heat dissipation mechanism disposed on a surface of the package substrate opposite the first surface and configured to dissipate heat of the package substrate.
   (4)

The semiconductor apparatus according to any one of (1) to (3) above, further including:
a sealing member that is disposed between the first surface and the cover plate so as to surround the opening portion of the recess portion and that hermetically seals an interior space of the recess portion.
   (5)

The semiconductor apparatus according to (4) above, in which a material for the sealing member includes a solder.

(6)

The semiconductor apparatus according to (4) above, in which a material for the sealing member includes a resin.

(7)

The semiconductor apparatus according to any one of (1) to (6) above, in which the first electrode includes a pad formed in the region on the edge side of the sensor chip and connected to a wiring inside the sensor chip.

(8)

The semiconductor apparatus according to any one of (1) to (7) above, further including:
an interior wiring disposed inside a wall portion of the recess portion of the package substrate and having one end connected to a first terminal exposed to a surface of the package substrate opposite the first surface and another end connected to a second terminal exposed to the first surface, in which
the second terminal and the second electrode are configured to be electrically connected to each other.
   (9)

A semiconductor apparatus including:
a package substrate having a recess portion on a first surface;
a sensor chip disposed inside the recess portion and having a pixel region in which photoelectric conversion sections are arranged;
a transparent cover plate disposed on the first surface and covering an opening portion of the recess portion; and
a resistive heating element disposed in a region within a surface of the cover plate facing the sensor chip, the region excluding a region facing the pixel region.
   (10)

The semiconductor apparatus according to (9) above, further including:
a heat insulating member that is formed in the region of the cover plate excluding the region facing the pixel region and that covers the resistive heating element.
   (11)

The semiconductor apparatus according to (10) above, in which a color of the heat insulating member includes black.

(12)

The semiconductor apparatus according to any one of (9) to (11) above, further including:
a Peltier element disposed between the sensor chip and a bottom surface of the recess portion and configured to absorb heat from the sensor chip and dissipate the heat to the package substrate.
   (13)

The semiconductor apparatus according to any one of (9) to (12) above, further including:
a sealing member that is disposed between the first surface and the cover plate so as to surround the opening portion of the recess portion and that hermetically seals an interior space of the recess portion.
   (14)

The semiconductor apparatus according to (13) above, in which a material for the sealing member includes a resin.

(15)

The semiconductor apparatus according to any one of (9) to (14) above, further including:
an interior wiring disposed inside a wall portion of the recess portion of the package substrate and having one end connected to a first terminal exposed to a surface of the package substrate opposite the first surface and another end connected to a second terminal exposed to the first surface, in which
the second terminal and the resistive heating element are configured to be electrically connected to each other by a silver paste.
   (16)

An electronic device including:
a semiconductor apparatus including
   a package substrate having a recess portion on a first surface,
   a sensor chip disposed inside the recess portion and having a pixel region in which photoelectric conversion sections are arranged,
   a transparent cover plate disposed on the first surface and covering an opening portion of the recess portion, and
   a thermoelectric element module disposed between the sensor chip and the cover plate, in which
the thermoelectric element module includes
   a first electrode formed in a region within a surface of the sensor chip facing the cover plate, the region being on an edge side of the sensor chip with respect to the pixel region,
   a second electrode formed in a region within a surface of the cover plate facing the sensor chip, the region facing the region on the edge side, and
   at least a pair of thermoelectric elements disposed between the first and second electrodes and configured to be electrically connected to the first and second electrodes so as to absorb heat from the sensor chip and dissipate the heat to the cover plate.
      (17)

An electronic device including:
a semiconductor apparatus including
   a package substrate having a recess portion on a first surface,
   a sensor chip disposed inside the recess portion and having a pixel region in which photoelectric conversion sections are arranged,
   a cover plate disposed on the first surface and covering an opening portion of the recess portion, and
   a resistive heating element disposed in a region within a surface of the cover plate facing the sensor chip, the region excluding a region facing the pixel region.

### REFERENCE SIGNS LIST

1: Semiconductor apparatus
2: Sensor chip
3: Package substrate
4: Cover plate
5: Thermoelectric element module
6: Heat dissipation mechanism
7: Pixel region
8: First region
9: Bonding pad
10: Bottom portion
11: Wall portion
12: Recess portion
13: Adhesive
14: Bonding pad
15: Bonding wire
17: Second region
18: Metal film
19: Sealing member
19a: Resin
20₁ to 20₆: First electrode
21₁ to 21₈: Second electrode
22₁ to 22₁₂: Thermoelectric element
23: Photoelectric conversion section
24: Third region
25: Fourth region
26: Solder
27: Base portion
28: Heat dissipation fin
29: Peltier element
30: Adhesive
31: Adhesive
32: Ultraviolet light
33₁ to 33₄: Wiring
34: First terminal
35₁ to 35₈: Second terminal
51₁, 51₂: Resistive heating element
52: Heat insulating member
53: Peltier element
54: First recess portion
55: Second recess portion
56, 57: Adhesive
58: Fifth region
59: Sixth region
60: Silver paste

1. A semiconductor apparatus comprising:
a package substrate having a recess portion on a first surface;
a sensor chip disposed inside the recess portion and having a pixel region in which photoelectric conversion sections are arranged;
a transparent cover plate disposed on the first surface and covering an opening portion of the recess portion; and
a thermoelectric element module disposed between the sensor chip and the cover plate, wherein
the thermoelectric element module includes
a first electrode formed in a region within a surface of the sensor chip facing the cover plate, the region being on an edge side of the sensor chip with respect to the pixel region,
a second electrode formed in a region within a surface of the cover plate facing the sensor chip, the region facing the region on the edge side, and
at least a pair of thermoelectric elements disposed between the first and second electrodes and configured to be electrically connected to the first and second electrodes so as to absorb heat from the sensor chip and dissipate the heat to the cover plate.

2. The semiconductor apparatus according to claim 1, further comprising:
a Peltier element disposed between the sensor chip and a bottom surface of the recess portion and configured to absorb heat from the sensor chip and dissipate the heat to the package substrate.

3. The semiconductor apparatus according to claim 1, further comprising:
a heat dissipation mechanism disposed on a surface of the package substrate opposite the first surface and configured to dissipate heat of the package substrate.

4. The semiconductor apparatus according to claim 1, further comprising:
a sealing member that is disposed between the first surface and the cover plate so as to surround the opening portion of the recess portion and that hermetically seals an interior space of the recess portion.

5. The semiconductor apparatus according to claim 4, wherein a material for the sealing member includes a solder.

6. The semiconductor apparatus according to claim 4, wherein a material for the sealing member includes a resin.

7. The semiconductor apparatus according to claim 1, wherein the first electrode includes a pad formed in the region on the edge side of the sensor chip and connected to a wiring inside the sensor chip.

8. The semiconductor apparatus according to claim 1, further comprising:
an interior wiring disposed inside a wall portion of the recess portion of the package substrate and having one end connected to a first terminal exposed to a surface of the package substrate opposite the first surface and another end connected to a second terminal exposed to the first surface, wherein
the second terminal and the second electrode are configured to be electrically connected to each other.

9. A semiconductor apparatus comprising:
a package substrate having a recess portion on a first surface;
a sensor chip disposed inside the recess portion and having a pixel region in which photoelectric conversion sections are arranged;
a transparent cover plate disposed on the first surface and covering an opening portion of the recess portion; and
a resistive heating element disposed in a region within a surface of the cover plate facing the sensor chip, the region excluding a region facing the pixel region.

10. The semiconductor apparatus according to claim 9, further comprising:
a heat insulating member that is formed in the region of the cover plate excluding the region facing the pixel region and that covers the resistive heating element.

11. The semiconductor apparatus according to claim 10, wherein a color of the heat insulating member includes black.

12. The semiconductor apparatus according to claim 9, further comprising:
a Peltier element disposed between the sensor chip and a bottom surface of the recess portion and configured to absorb heat from the sensor chip and dissipate the heat to the package substrate.

13. The semiconductor apparatus according to claim 9, further comprising:
a sealing member that is disposed between the first surface and the cover plate so as to surround the opening portion of the recess portion and that hermetically seals an interior space of the recess portion.

14. The semiconductor apparatus according to claim 13, wherein a material for the sealing member includes a resin.

15. The semiconductor apparatus according to claim 9, further comprising:
an interior wiring disposed inside a wall portion of the recess portion of the package substrate and having one end connected to a first terminal exposed to a surface of the package substrate opposite the first surface and another end connected to a second terminal exposed to the first surface, wherein
the second terminal and the resistive heating element are configured to be electrically connected to each other by a silver paste.

16. An electronic device comprising:
a semiconductor apparatus including
a package substrate having a recess portion on a first surface,
a sensor chip disposed inside the recess portion and having a pixel region in which photoelectric conversion sections are arranged,
a transparent cover plate disposed on the first surface and covering an opening portion of the recess portion, and
a thermoelectric element module disposed between the sensor chip and the cover plate, wherein
the thermoelectric element module includes
a first electrode formed in a region within a surface of the sensor chip facing the cover plate, the region being on an edge side of the sensor chip with respect to the pixel region,
a second electrode formed in a region within a surface of the cover plate facing the sensor chip, the region facing the region on the edge side, and
at least a pair of thermoelectric elements disposed between the first and second electrodes and configured to be electrically connected to the first and second electrodes so as to absorb heat from the sensor chip and dissipate the heat to the cover plate.

17. An electronic device comprising:
a semiconductor apparatus including
a package substrate having a recess portion on a first surface,
a sensor chip disposed inside the recess portion and having a pixel region in which photoelectric conversion sections are arranged,
a cover plate disposed on the first surface and covering an opening portion of the recess portion, and
a resistive heating element disposed in a region within a surface of the cover plate facing the sensor chip, the region excluding a region facing the pixel region.
